(19) United States
(12) Patent Application Publication
(10) Pub. No.: US 2026/0107429 A1
(43) Pub. Date: Apr. 16, 2026

(54) MEMORY DEVICES CONFIGURED IN CFET STRUCTURES AND METHODS FOR MANUFACTURING THE SAME

(71) Applicant: Taiwan Semiconductor Manufacturing Company, Ltd., Hsinchu (TW)

(72) Inventors: Ping-Wei Wang, New Taipei City 242 (TW); Jui-Lin Chen, Hsinchu (TW); Kian-Long Lim, Taipei City (TW)

(73) Assignee: Taiwan Semiconductor Manufacturing Company, Ltd., Hsinchu (TW)

(21) Appl. No.: 19/170,961

(22) Filed: Apr. 4, 2025

Related U.S. Application Data
(60) Provisional application No. 63/707,621, filed on Oct. 15, 2024.

(51) Int. Cl. H10B 10/00; G11C 5/06; G11C 11/412; G11C 11/419; H10D 30/00; H10D 30/01; H10D 30/43; H10D 62/10

(52) U.S. Cl. CPC H10B 10/12; G11C 5/063; G11C 11/412; G11C 11/419; H10D 30/014; H10D 30/0191; H10D 30/43; H10D 30/502; H10D 62/121

(57) ABSTRACT

A memory device includes a substrate having a first side and a second side opposite to each other; a first transistor, a second transistor, and a third transistor formed at a first level on the first side of the substrate, the first to third transistors each formed with a first conductivity; and a fourth transistor, a fifth transistor, a sixth transistor, and a seventh transistor formed at a second level on the first side of the substrate, the fourth to seventh transistors each formed with a second conductivity, wherein the first level is vertically disposed with respect to the second level. The first to seventh transistors operatively form a Static Random Access Memory (SRAM) cell.

### CROSS-REFERENCE TO RELATED APPLICATION

This application claims priority to and the benefit of U.S. Provisional Application Number 63/707,621, filed Oct. 15, 2024, entitled “SRAM DEVICE EMPLOYING CFET STRUCTURE,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example circuit diagram of a memory cell, in accordance with some embodiments.

FIGS. 2-7 illustrate layouts that are collectively configured to form the memory cell of FIG. 1 in a CFET structure, in accordance with some embodiments.

FIG. 8 and FIG. 9 collectively illustrate an example map of a memory array including a plural number of the memory cells of FIG. 1, in accordance with some embodiments.

FIG. 10 illustrates a cross-sectional view of a semiconductor device formed based on the map of FIGS. 8-9, in accordance with some embodiments.

FIG. 11 and FIG. 12 collectively illustrate another example map of a memory array including a plural number of the memory cells of FIG. 1, in accordance with some embodiments.

FIG. 13 and FIG. 14 collectively illustrate yet another map of a memory array including a plural number of the memory cells of FIG. 1, in accordance with some embodiments.

FIG. 15 illustrates another example circuit diagram of a memory cell, in accordance with some embodiments.

FIG. 16 illustrates yet another example circuit diagram of a memory cell, in accordance with some embodiments.

FIG. 17 illustrates yet another example circuit diagram of a memory cell, in accordance with some embodiments.

FIG. 18 and FIG. 19 collectively illustrate an example map of a memory array including a plural number of the memory cells of FIG. 16, in accordance with some embodiments.

FIG. 20 illustrates a cross-sectional view of a semiconductor device formed based on the map of FIGS. 18-19, in accordance with some embodiments.

FIG. 21 illustrates an example flow chart of a method for forming a semiconductor device including a memory cell configured with a CFET structure, in accordance with some embodiments.

FIGS. 22-30 illustrate cross-sectional views of an example semiconductor device during various fabrication stages, made by the method of FIG. 21, in accordance with some embodiments.

FIG. 31 illustrates an example flow chart of a method for forming a semiconductor device including a memory cell configured with a CFET structure, in accordance with some embodiments.

FIGS. 32-42 illustrate cross-sectional views of an example semiconductor device during various fabrication stages, made by the method of FIG. 31, in accordance with some embodiments.

FIG. 43 illustrates a cross-sectional view of a semiconductor device formed based on the map of FIGS. 8-9, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary field-effect transistors (CFETs) are one type of gate-all-around (GAA) field-effect transistors. In general, a GAA FET includes a plural number of nanostructures, such as nanosheets or nanowires, vertically stacked on top of one another. P-type and n-type GAA FETs are formed on the same horizontal plane over a substrate and are separated by isolation structures. In contrast, a CFET is commonly fabricated by vertically stacking a p-type GAA FET and an n-type GAA FET on top of each other. This stacking configuration of n-type and p-type transistors in a single structure eliminates the need for an n-to-p separation, reduces the active area footprint, and increases the transistor density within a chip. This stacking concept is not limited to GAA FETs; for example, CFETs can be formed with FinFET devices or with a combination of GAA FETs and FinFETs.

Static random access memory (SRAM) cells are commonly used in integrated circuits. SRAM cells have the advantageous feature of holding data without a need for refreshing. SRAM cells may include different numbers of transistors, and are often referred to by the number of transistors, for example, a six-transistor (6T) SRAM cell, a seven-transistor (7T) SRAM cell, an eight-transistor (8T) SRAM cell, and the like. The transistors typically form a data latch for storing a bit. Additional transistors may be added to control the access to the transistors. SRAM cells are typically arranged as an array having rows and columns. Each row of the SRAM cells is connected to a word line (WL), which determines whether an SRAM cell is selected or not. Each column of the SRAM cells is connected to a bit line (BL), or a pair of complementary bit lines (BL and BLB), which is used for storing a bit into, or read from, the SRAM cell.

Generally, a multi-port SRAM cell (e.g., the 7T SRAM cell, the 8T SRAM cell) has the advantage over a single-port SRAM cell (e.g., the 6T SRAM cell) by allowing simultaneous read and write operations to different memory locations at the same time, which significantly increases system bandwidth and is particularly useful in applications where multiple processors or units need to access memory concurrently, leading to improved performance and efficiency compared to a single-port design. Some example advantages that a multi-port SRAM cell can provide over a single-port SRAM can include, but are not limited to, parallel access, higher throughput, reduced latency, more suitable for high-performance applications, etc.

It has been proposed to form the multi-port SRAM cell based on the CFET structures. For example, to form a multi-port SRAM cell with eight transistors, a first level including a number of p-type transistors (e.g., two pull-up transistors) is first formed on the frontside of a substrate, followed by a second level including a number of n-type transistors (e.g., two pull-down transistors, two read write-gate transistors, and two read pass-gate transistors) formed over the first level. That is, the existing 8T SRAM cell has six of its transistors formed at the second level, with only two transistors formed at the first level, which disadvantageously increases an occupied area of each SRAM cell. Such inefficient area usage can negatively impact integration of the multi-port SRAM cells into integrated circuits that keep being scaled down. Thus, the existing CFET structures configured for forming multi-port memory cells have not been entirely satisfactory in certain aspects.

The present disclosure provides various embodiments of a semiconductor device (e.g., a memory device) formed in a CFET structure that has first and second frontside levels over a substrate for forming respectively different conductive types of transistors. According to various embodiments of the present disclosure, the memory device may include plural multi-port SRAM cells, each of which includes plural (e.g., more than 6) transistors. In one aspect, the multi-port SRAM cell, as disclosed herein, can include seven transistors. For example, first and second pull-up transistors and a read pass-gate transistor, configured in p-type, are formed at the first frontside level; and first and second write pass-gate transistors and first and second pull-down transistors, configured in n-type, are formed at the second frontside level. In another aspect, the multi-port SRAM cell, as disclosed herein, can include eight transistors. For example, first and second pull-up transistors and first and second read pass-gate transistors, configured in p-type, are formed at the first frontside level; and first and second write pass-gate transistors and first and second pull-down transistors, configured in n-type, are formed at the second frontside level. Further, the disclosed multi-port SRAM cells can each be formed based on a 4CPP configuration, e.g., up to four transistors of the SRAM cell available to be formed along one common active region. As such, the p-type read-port transistors (e.g., the read pass-gate transistor) can be formed vertically below the n-type write-port transistors (e.g., the write pass-gate transistor). Stated another way, the read pass-gate transistor(s) can be formed with the same active region as the p-type pull-up transistors, which requires no additional area (e.g., another active region) to form the read-port transistors. Advantageously, no area penalty results from the disclosed multi-port SRAM cell, allowing a significantly large number of these multi-port SRAM cells to seamlessly integrate with advanced integrated circuits.

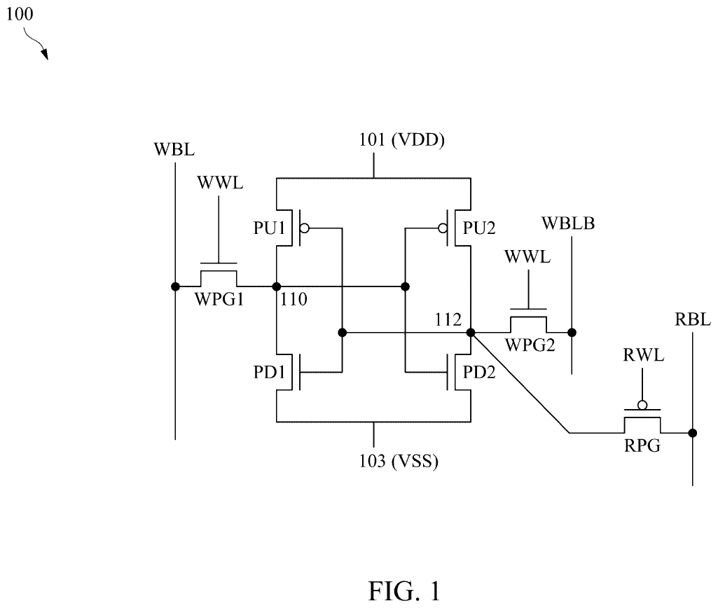

FIG. 1 illustrates an example circuit diagram of a memory cell 100, in accordance with some embodiments. As shown, the memory cell 100 includes seven transistors that operatively form a 7T SRAM cell. In various embodiments, the seven transistors can be physically formed with a CFET structure, which will be discussed below. For example, the memory cell 100 includes transistors: a first pull-up transistor PU1, a second pull-up transistor PU2, a first pull-down transistor PD1, a second pull-down transistor PD2, a first write pass-gate transistor WPG1, a second write pass-gate transistor WPG2, and a read pass-gate transistor RPG.

The transistors PU1 and PD1 are formed as a first inverter and the transistors PU2 and PD2 are formed as a second inverter, wherein the first and second inverters are cross coupled to each other. For example, the transistors PU1 and PD1 have their respective source/drain terminals connected to each other at common node 110, which is further coupled to gate terminals of the transistors PU2 and PD2; and the transistors PU2 and PD2 have their respective source/drain terminals connected to each other at common node 112, which is further coupled to gate terminals of the transistors PU1 and PD1. Specifically, the first and second inverters are each coupled between first voltage reference 101 and second voltage reference 103. In some embodiments, the first voltage reference 101 is a supply voltage applied to the memory cell 100, sometimes referred to as “VDD,” and the second voltage reference 103 is a ground voltage, sometimes referred to as “VSS.” The first inverter (formed by the transistors PU1 and PD1) is coupled to the transistor WPG1 which is gated by a write word line (WWL), and the second inverter (formed by the transistors PU2 and PD2) is coupled to the transistor WPG2 which is also gate by the WWL. Further, the transistor WPG1 is coupled between a write bit line (WBL) and the node 110, and the transistor WPG2 is coupled between a write bit line bar (WBLB) and the node 112. The transistor RPG, gate by a read word line (RWL), is coupled between the node 112 and a read bit line (RBL). In some embodiments, the transistors WPG1 and WPG2 are sometimes referred to as a write port of the memory cell 100, and the transistor RPG is sometimes referred to as a read port of the memory cell 100.

With their gate terminals each coupled to the WWL, the transistors WPG1 and WPG2 are configured to receive a pulse signal through the WWL, to allow or block an access (e.g., a write operation) of the memory cell 100 accordingly. The transistors PD1 and PUI are coupled between VDD and VSS, and coupled to each other at node 110. For example, the transistor PU1 has a first source/drain terminal connected to VDD and the transistor PD1 has a first source/drain terminal connected to VSS, with the transistors PU1 and PD1 having their second source/drain terminals connected to each other at the node 110. The transistor WPG1 has a first source/drain terminal connected to the WBL and a second source/drain terminal connected to the node 110, which is further coupled to gate terminals of the transistors PU2 and PD2. Similarly, the transistors PD2 and PU2 are coupled between VDD and VSS, and coupled to each other at the node 112. For example, the transistor PU2 has a first source/drain terminal connected to VDD and the transistor PD2 has a first source/drain terminal connected to VSS, with the transistors PU2 and PD2 having their second source/drain terminals connected to each other at the node 112. The transistor WPG2 has a first source/drain terminal connected to the WBLB and a second source/drain terminal connected to the node 112, which is further coupled to gate terminals of the transistors PU1 and PD1.

In some embodiments, the transistors PU1, PU2, and RPG can each include a p-type metal-oxide-semiconductor (PMOS) transistor, and the transistors PD1, PD2, WPG1, and WPG2 can each include an n-type metal-oxide-semiconductor (NMOS) transistor. Although the illustrated embodiment of FIG. 1 shows that the transistors of the memory cell 100 are either NMOS or PMOS transistors, any of a variety of transistors or devices that are suitable for use in a memory device may be implemented as at least one of the transistors of the memory cell 100 such as, for example, a bipolar junction transistor (BJT), a high-electron-mobility transistor (HEMT), etc. Further, as will be discussed below, the p-type transistors, PU1, PU2, and RPG, are each formed as a GAA FET in a first level disposed on the frontside of a substrate, and the n-type transistors, PD1, PD2, WPG1, and WPG2, are each formed as a GAA FET in a second level over the first level.

In some other embodiments, the transistors PU1, PU2, WPG1, and WPG2 can each include a PMOS transistor, and the transistors PD1, PD2, and RPG can each include an NMOS transistor. For example, the p-type transistors, PU1, PU2, WPG1, and WPG2, are each formed as a GAA FET in a first level disposed on the frontside of a substrate, and the n-type transistors, PD1, PD2, and RPG, are each formed as a GAA FET in a second level over the first level.

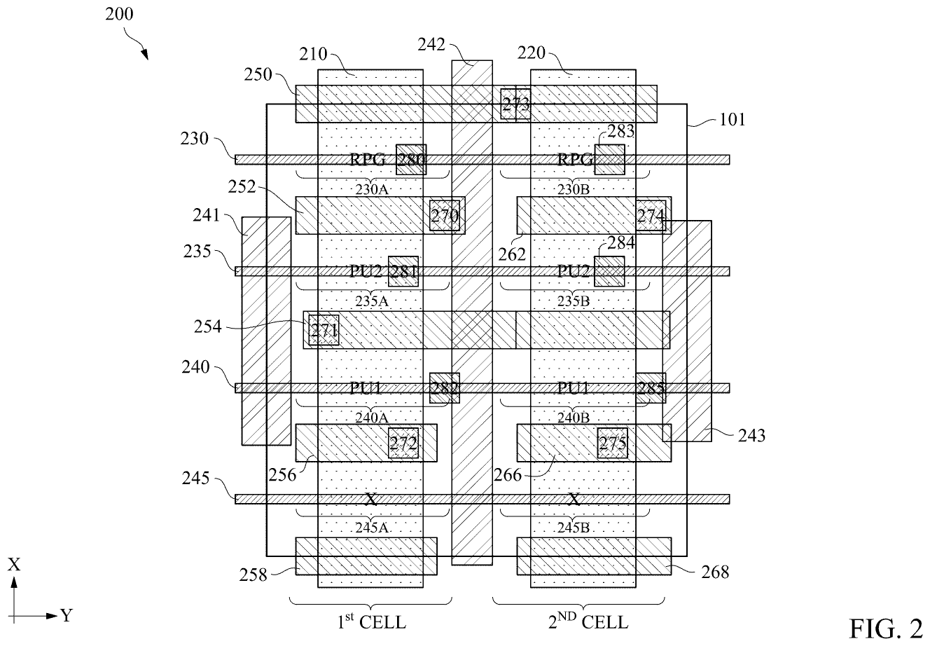

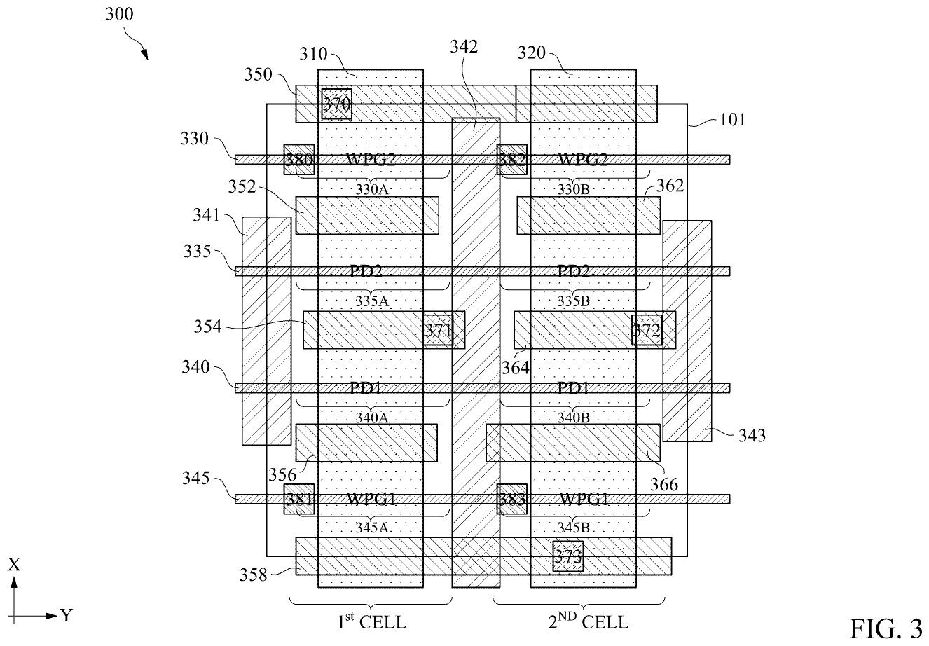

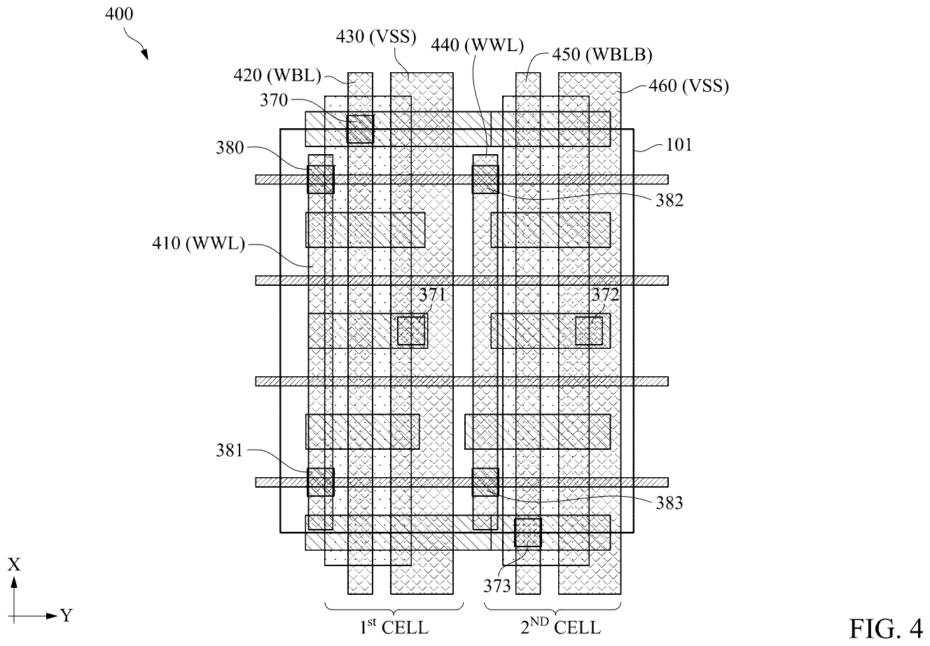

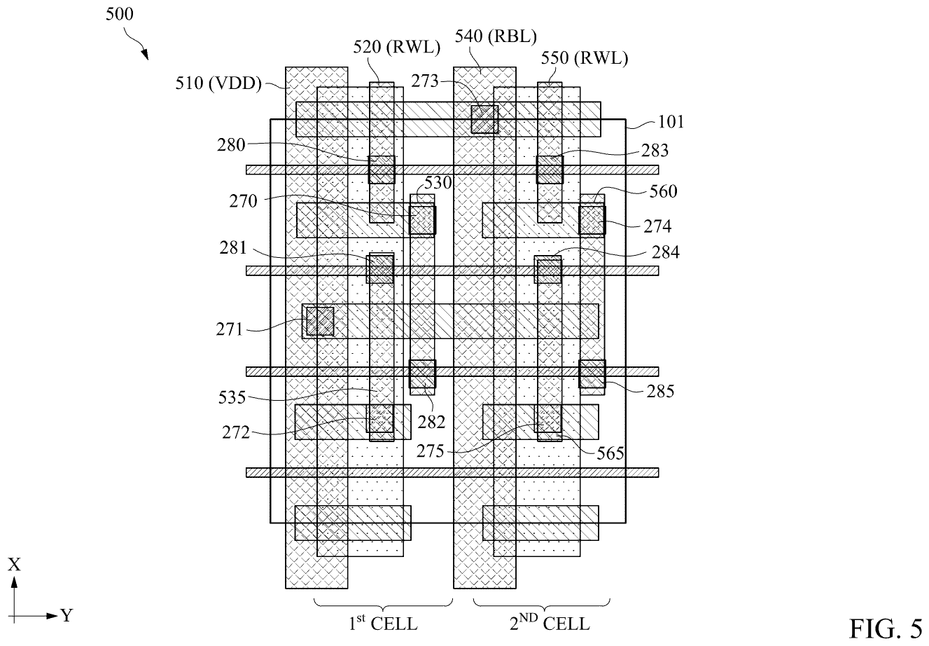

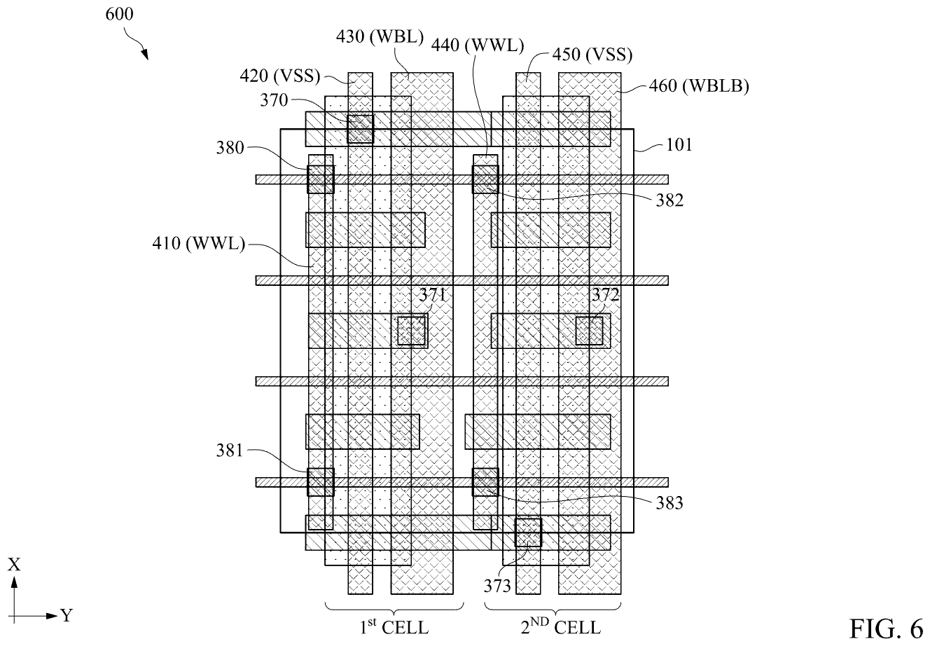

FIG. 2, FIG. 3, FIG. 4, FIG. 5, FIG. 6, and FIG. 7 respectively illustrate layouts 200, 300, 400, 500, 600, and 700 that can be collectively utilized to form two of the memory cells 100 (FIG. 1) configured in a CFET structure. For example, the layouts 200, 300, 400, and 500 can collectively form two of the memory cells 100 (e.g., arranged along the same row or same WL). In another example, the layouts 200, 300, 600, and 700 can collectively form two of the memory cells 100 (e.g., arranged along the same row or same WL). It should be understood that each of the layouts 200 to 700 has been simplified for illustrative purposes, and thus, can include any of various other patterns (or structures) while remaining within the scope of the present disclosure.

As depicted, each of the layouts 200 to 700 includes a cell boundary 101 defining a physical area for those two memory cells 100 (1^{st} memory cell and 2^{nd} memory cell), each of which includes seven transistors configured with a CFET structure. The CFET structure can include a number of first transistors disposed at a first level on the frontside of a substrate, and a number of second transistors despised at a second, upper level on the frontside of the substrate. In some embodiments, each of these first and second transistors is configured as a GAA FET, while the first transistors and the second transistors have opposite conductive types. In some other embodiments, each of the first and second transistors can be formed as other type of transistor structures while remaining within the scope of the present disclosure.

Generally, each of the layouts 200 to 700 can include a number of patterns configured for forming respective structures, and thus, such patterns of the disclosed layout are herein referred to as the structures to be formed, respectively, in the following discussion. For example, the layout 200 is configured to form structures of the first transistors at the first level on the frontside; the layout 300 is configured to form structures of the second transistors at the second level on the frontside; the layout 400/600 is configured to form the structures at a third level on the frontside of the substrate, over the second level; and the layout 500/700 is configured to form the structures at a first level on a backside of the substrate.

Referring first to FIG. 2, the layout 200 can include patterns for forming active regions 210 and 220, and gate structures 230, 235, 240, and 245, respectively. The active regions 210 and 220 may extend in the X-direction; and the gate structures 230 to 245 may extend in the Y-direction. Each of the active regions 210 and 220 may be formed as a fin structure or a stack structure extending along the X-direction, and each of the gate structures 230 to 245 may be formed to extend in the Y-direction to traverse the active regions 210 and 220. The layout 200 can further include a number of cut patterns, e.g., 241, 242, and 243, each of which can extend along the X-direction traversing one or more of the gate structures 230-245. The cut patterns 241 to 243 can each be configured to form a dielectric structure, thereby dividing one or more of the gate structures 230-245 into separate gate sections. For example, the cut pattern 242 can divide the gate structure 230 into gate sections 230A and 230B, divide the gate structure 235 into gate sections 235A and 235B, divide the gate structure 240 into gate sections 240A and 240B, and divide the gate structure 245 into gate sections 245A and 245B, as indicated in FIG. 2.

Referring next to FIG. 3, the layout 300 can include patterns for forming active regions 310 and 320, and gate structures 330, 335, 340, and 345, respectively. The active regions 310 and 320 may extend in the X-direction; and the gate structures 330 to 345 may extend in the Y-direction. Each of the active regions 310 and 320 may be formed as a fin structure or a stack structure extending along the X-direction, and each of the gate structures 330 to 345 may be formed to extend in the Y-direction to traverse the active regions 310 and 320. The layout 300 can further include a number of cut patterns, e.g., 341, 342, and 343, each of which can extend along the X-direction traversing one or more of the gate structures 330-345. The cut patterns 341 to 343 can each be configured to form a dielectric structure, thereby dividing one or more of the gate structures 330-345 into separate gate sections. For example, the cut pattern 342 can divide the gate structure 330 into gate sections 330A and 330B, divide the gate structure 335 into gate sections 335A and 335B, divide the gate structure 340 into gate sections 340A and 340B, and divide the gate structure 345 into gate sections 345A and 345B, as indicated in FIG. 3.

In some embodiments, the active regions 210 and 310 are vertically aligned with each other, the active regions 220 and 320 are vertically aligned with each other, the gate structures 230 and 330 are vertically aligned with each other, the gate structures 235 and 335 are vertically aligned with each other, the gate structures 240 and 340 are vertically aligned with each other, and the gate structures 245 and 345 are vertically aligned with each other. Further, the cut patterns 241 and 341 are vertically aligned with each other, the cut patterns 242 and 342 are vertically aligned with each other, and the cut patterns 243 and 343 are vertically aligned with each other. The active regions 210 and 310 may be physically formed as a single structure (sometimes referred to as “active region 210/310”), the active regions 220 and 320 may be physically formed as a single structure (sometimes referred to as “active region 220/320”), the gate structures 230 and 330 may be physically formed as a single structure (sometimes referred to as “gate structure 230/330”), the gate structures 235 and 335 may be physically formed as a single structure (sometimes referred to as “gate structure 235/335”), the gate structures 240 and 340 may be physically formed as a single structure (sometimes referred to as “gate structure 240/340”), and the gate structures 245 and 345 may be physically formed as a single structure (sometimes referred to as “gate structure 245/345”).

As will be discussed below, except the gate structures 230/330 and 245/345, each of the gate structures 235/335 and 240/340 can include a lower portion and an upper portion, corresponding to the first level and the second level, respectively, where the lower portion and the upper portion are electrically coupled to each other even with a dielectric layer vertically interposed therebetween. In some embodiments, each of the gate structures 230/330 and 245/345 can also include a lower portion and an upper portion, corresponding to the first level and the second level, respectively, but the lower portion and the upper portion are electrically isolated from each other with a dielectric layer vertically interposed therebetween. Stated another way, the corresponding dielectric layer can completely separate the lower and upper portion of the gate structure 230/330 or 245/345, while the corresponding dielectric layer can partially separate the lower and upper portion of each of the gate structures 235/335 and 240/340.

For example, the active region 210/310 and active region 220/320 can each be first formed as a stack structure protruding from the frontside surface of a substrate. The stack may include a number of first semiconductor nanostructures (e.g., first nanosheets) extending along the X-direction and vertically separated from each other, and a number of second semiconductor nanostructures (e.g., second nanosheets) extending along the X-direction and vertically separated from each other. The first nanosheets are positioned at the first level, and the second nanosheets are positioned at the second level. According to some embodiments of the present disclosure, the first nanosheets, formed based on a lower portion of the active region 210/310 or a lower portion of the active region 220/320, can partially form the first transistors formed at the first level; and the second nanosheets, formed based on an upper portion of the active region 210/310 or an upper portion of the active region 220/320, can partially form the second transistors formed at the second level. Further, the first nanosheets and the second nanosheets can be vertically aligned with but separated from each other, with at least one dielectric layer interposed therebetween.

Next, respective portions of the first and second nanosheets in each of the stacks that are overlaid by the gate structures 230/330 to 245/345, which are initially formed as a number of dummy (e.g., polysilicon) gate structures, respectively, may remain. Other portions of the first nanosheets are replaced with a number of first epitaxial structures, and other portions of the second nanosheets are replaced with a number of second epitaxial structures. According to some embodiments of the present disclosure, the first epitaxial structures (at the first level) may be formed with a p-type conductivity, and the second epitaxial structures (at the second level) may be formed with an n-type conductivity. The first epitaxial structures can operatively form respective source/drain terminals of the first transistors at the first level, and the second epitaxial structures can operatively form respective source/drain terminals of the second transistors at the second level.

Next, each of the dummy gate structures 230/330 to 245/345 can be replaced by a corresponding active (e.g., metal) gate structure to form the first and second transistors. As mentioned above, each of the active gate structures can include a lower portion and an upper portion corresponding to the first level and the second level, respectively. Further, the lower and upper portion of the active gate structure 230/330 or 245/345 may be electrically isolated from each other, while the lower and upper portion of each of the active gate structures 235/335 and 240/340 may be electrically coupled to each other. For example, the lower portion of the active gate structure may include one or more first work function metals configured for forming a gate terminal of one of the first transistors with the p-type conductivity, and the upper portion of the active gate structure may include one or more second work function metals configured for forming a gate terminal of one of the second transistors with the n-type conductivity. Details of a series of manufacturing processes to form the structures of the first transistors at the first level and the second transistors at the second level will be described with respect to FIGS. 25-43.

As a brief overview, the transistors PU1, PU2, and RPG of each the first and second memory cells 100 can be formed at the first level based on the layout 200 (as indicated in FIG. 2), and the transistors WPG1, WPG2, PD1, and PD2 of each of the first and second memory cells 100 can be formed at the second level based on the layout 300 (as indicated in FIG. 3). Further, a dummy transistor can be formed at the first level (indicated by a symbolic “X” in FIG. 2). In some embodiments, the transistors PU1, PU2, and RPG at the first level can be formed with the p-type conductivity, and the transistors WPG1, WPG2, PD1, and PD2 at the second level can be formed with the n-type conductivity.

Using the first memory cell 100 as a representative example, in FIG. 2, the transistor PU2 can include its channel, gate terminal, and source/drain terminals formed by a subset of the first nanosheets in the active region 210, the gate section 235A, and a subset of the first epitaxial structures formed from the active region 210 and disposed on opposite sides of the gate structure 235A, respectively. The transistor PU1 can include its channel, gate terminal, and source/drain terminals formed by another subset of the first nanosheets in the active region 210, the gate section 240A, and another subset of the first epitaxial structures formed from the active region 210 and disposed on opposite sides of the gate structure 240A, respectively. The transistor RPG can include its channel, gate terminal, and source/drain terminals formed by yet another subset of the first nanosheets in the active region 210, the gate section 230A, and yet another subset of the first epitaxial structures formed from the active region 210 and disposed on opposite sides of the gate structure 230A, respectively.

In FIG. 3, the transistor WPG2 can include its channel, gate terminal, and source/drain terminals formed by a subset of the second nanosheets in the active region 310, the gate section 330A, and a subset of the second epitaxial structures formed from the active region 310 and disposed on opposite sides of the gate structure 330A, respectively. The transistor PD2 can include its channel, gate terminal, and source/drain terminals formed by another subset of the second nanosheets in the active region 310, the gate section 335A, and another subset of the second epitaxial structures formed from the active region 310 and disposed on opposite sides of the gate structure 335A, respectively. The transistor PD1 can include its channel, gate terminal, and source/drain terminals formed by another subset of the second nanosheets in the active region 310, the gate section 340A, and another subset of the second epitaxial structures formed from the active region 310 and disposed on opposite sides of the gate structure 340A, respectively. The transistor WPG1 can include its channel, gate terminal, and source/drain terminals formed by a subset of the second nanosheets in the active region 310, the gate section 345A, and a subset of the second epitaxial structures formed from the active region 310 and disposed on opposite sides of the gate structure 345A, respectively.

Referring again to FIG. 2, the layout 200 can further include patterns for forming source/drain contact structures 250, 252, 254, 256, 258, 262, 266, and 268, respectively. Similarly in FIG. 3, the layout 300 can further include patterns for forming source/drain contact structures 350, 352, 354, 356, 358, 362, 364, and 366, respectively. Such source/drain contact structures 250 to 268 and 350 to 366 are each sometimes referred to as MD. In general, each of these MDs 250 to 268 and 350 to 366 is configured to electrically connect to the source/drain terminal of a corresponding transistor. For example, each of the MDs 250 to 268 and 350 to 366 can be physically coupled to or wrap around the epitaxial structure of a corresponding transistor. In some embodiments, each of the MDs 250 to 268 and 350 to 366 can laterally extend along the same direction as the gate structures 230-245 and 330-345, e.g., the Y-direction.

For example, in FIG. 2, the MD 252 is connected to the second source/drain terminal of the transistor PU2 of the first memory cell 100 and the first source/drain terminal of the transistor RPG of the first memory cell 100; the MD 254 is connected to the first source/drain terminals of the transistor PU2 and the first source/drain terminal of the transistor PU1 of each of the first and second memory cells 100; the MD 256 is connected to the second source/drain terminal of the transistor PU1 of the first memory cell 100; the MD 266 is connected to the second source/drain terminal of the transistor PU1 of the second memory cell 100; the MD 262 is connected to the second source/drain terminal of the transistor PU2 of the second memory cell 100 and the first source/drain terminal of the transistor RPG of the second memory cell 100; and the MD 250 is connected to the second source/drain terminal of the transistor RPG of each of the first and second memory cells 100.

In FIG. 3, the MD 350 is connected to the first source/drain terminals of the transistor WPG2 of each of the first and second memory cells 100; the MD 352 is connected to the second source/drain terminal of the transistor WPG2 and the second source/drain terminals of the transistor PD2 of the first memory cell 100; the MD 362 is connected to the second source/drain terminal of the transistor WPG2 and the second source/drain terminals of the transistor PD2 of the second memory cell 100; the MD 354 is connected to the first source/drain terminal of the transistor PD2 and the first source/drain terminals of the transistor PD1 of the first memory cell 100; the MD 364 is connected to the first source/drain terminal of the transistor PD2 and the first source/drain terminals of the transistor PD1 of the second memory cell 100; the MD 356 is connected to the second source/drain terminal of the transistor PD1 and the second source/drain terminals of the transistor WPG1 of the first memory cell 100; the MD 366 is connected to the second source/drain terminal of the transistor PD1 and the second source/drain terminals of the transistor WPG1 of the second memory cell 100; and the MD 358 is connected to the first source/drain terminal of the transistor WPG1 of each of the first and second memory cells 100.

In some embodiments, the MD 252 (FIG. 2) and MD 352 (FIG. 3) may be connected to each other through a first via structure (not shown), and the MD 256 (FIG. 2) and MD 356 (FIG. 3) may be connected to teach other through a second via structure (not shown). Stated another way, the first via structure can vertically extend from the first level to the second level to connect the MD 252 to the MD 352, and the second via structure can vertically extend from the first level to the second level to connect the MD 256 to the MD 356. As such, the (internal) node 112 of the first memory cell 100, at which the respective source/drain terminals of the transistors PU2, PD2, and RPG are connected to one another, can be partially formed based on the MID 252, the MD 352, and the first via structure vertically interposed therebetween; and the (internal) node 110 of the first memory cell 100, at which the respective source/drain terminals of the transistors PU1 and PD2 are connected to one another, can be operatively formed based on the MD 256, the MD 356, and the second via structure vertically interposed therebetween. The nodes 110 and 112 of the second memory cell 100 can be partially formed in similar fashion.

Referring again to FIG. 2, the layout 200 can further include patterns for forming a number of via structures 270, 271, 272, 273, 274, and 275, respectively. In some embodiments, each of the via structures 270 to 275 can be formed below an MD included in the layout 200. Particularly, the via structures 270 to 275 can each downwardly extend from the frontside of the substrate (e.g., the first level on the frontside) to the backside of the substrate (e.g., the first level on the backside). Such via structures 270 to 275 are each sometimes referred to as BVD.

For example, the BVD 273 is formed below the MD 250, allowing the MID 250 to be electrically connected to one or more interconnect structures formed in the first level on the backside (e.g., an interconnect structure configured as the RBL for the first and second memory cells 100, which is formed based on the layout 500/700); the BVD 271 is formed below the MD 254, allowing the MD 254 to be electrically connected to one or more interconnect structures formed in the first level on the backside (e.g., an interconnect structure configured as a power rail carrying VDD, which is formed based on the layout 500/700); the BVD 270 is formed below the MD 252, allowing the MD 252 to be electrically connected to one or more interconnect structures formed in the first level on the backside (e.g., a first internal contact structure of the first memory cell 100, which is formed based on the layout 500/700); the BVD 272 is formed below the MD 256, allowing the MD 256 to be electrically connected to one or more interconnect structures formed in the first level on the backside (e.g., a second internal contact structure of the first memory cell 100, which is formed based on the layout 500/700); the BVD 274 is formed below the MD 262, allowing the MD 262 to be electrically connected to one or more interconnect structures formed in the first level on the backside (e.g., a first internal contact structure of the second memory cell 100, which is formed based on the layout 500/700); and the BVD 275 is formed below the MD 266, allowing the MD 266 to be electrically connected to one or more interconnect structures formed in the first level on the backside (e.g., a second internal contact structure of the second memory cell 100, which is formed based on the layout 500/700).

The layout 200 can further include patterns for forming a number of via structures 280, 281, 282, 283, 284, and 285, respectively. In some embodiments, each of the via structures 280 to 285 can be formed below a gate structure (or gate section) included in the layout 200. Particularly, the via structures 280 to 285 can each downwardly extend from the frontside of the substrate (e.g., the first level on the frontside) to the backside of the substrate (e.g., the first level on the backside). Such via structures 280 to 285 are each sometimes referred to as BVG.

For example, the BVG 280 is formed below the gate section 230A, allowing the gate section 230A to be electrically connected to one or more interconnect structures formed in the first level on the backside (e.g., an interconnect structure configured as the RWL for the first memory cell 100, which is formed based on the layout 500/700); the BVG 283 is formed below the gate section 230B, allowing the gate section 230B to be electrically connected to one or more interconnect structures formed in the first level on the backside (e.g., an interconnect structure configured as the RWL for the second memory cell 100, which is formed based on the layout 500/700); the BVG 281 is formed below the gate section 235A, allowing the gate section 235A to be electrically connected to one or more interconnect structures formed in the first level on the backside (e.g., the second internal contact of the first memory cell 100, which is formed based on the layout 500/700); the BVG 284 is formed below the gate section 235B, allowing the gate section 235B to be electrically connected to one or more interconnect structures formed in the first level on the backside (e.g., the second internal contact of the second memory cell 100, which is formed based on the layout 500/700); the BVG 282 is formed below the gate section 240A, allowing the gate section 240A to be electrically connected to one or more interconnect structures formed in the first level on the backside (e.g., the first internal contact of the first memory cell 100, which is formed based on the layout 500/700); and the BVG 285 is formed below the gate section 240B, allowing the gate section 240B to be electrically connected to one or more interconnect structures formed in the first level on the backside (e.g., the first internal contact of the second memory cell 100, which is formed based on the layout 500/700).

Similarly, the layout 300 can further include patterns for forming a number of via structures 370, 371, 372, and 373, respectively. In some embodiments, each of the via structures 370 to 373 can be formed above an MD included in the layout 300. Particularly, the via structures 370 to 373 can each upwardly extend from the second level on the frontside to the third level on the frontside. Such via structures 370 to 373 are each sometimes referred to as VD.

For example, the VD 370 is formed above the MD 350, allowing the MD 350 to be electrically connected to one or more interconnect structures formed in the third level on the frontside (e.g., an interconnect structure configured as the WBL for the first and second memory cells 100, which is formed based on the layout 400); the VD 373 is formed above the MD 358, allowing the MD 358 to be electrically connected to one or more interconnect structures formed in the third level on the frontside (e.g., an interconnect structure configured as the WBLB for the first and second memory cells 100, which is formed based on the layout 400); the VD 371 is formed above the MD 354, allowing the MD 354 to be electrically connected to one or more interconnect structures formed in the third level on the frontside (e.g., an interconnect structure configured as a power rail carrying VSS for the first memory cell 100, which is formed based on the layout 400); and the VD 372 is formed above the MD 364, allowing the MID 364 to be electrically connected to one or more interconnect structures formed in the third level on the frontside (e.g., an interconnect structure configured as a power rail carrying VSS for the second memory cell 100, which is formed based on the layout 400).

The layout 300 can further include patterns for forming a number of via structures 380, 381, 382, and 383, respectively. In some embodiments, each of the via structures 380 to 383 can be formed above a gate structure (or gate section) included in the layout 300. Particularly, the via structures 380 to 383 can each upwardly extend from the second level on the frontside to the third level on the frontside. Such via structures 380 to 383 are each sometimes referred to as VG.

For example, the VG 380 is formed above the gate section 330A and the VG 381 is formed above the gate section 345A, allowing the gate section 330A and 345A to be electrically connected to one or more interconnect structures formed in the third level on the frontside (e.g., an interconnect structure configured as the WWL for the first memory cell 100, which is formed based on the layout 400); and the VG 382 is formed above the gate section 330B and the VG 383 is formed above the gate section 345B, allowing the gate section 330B and 345B to be electrically connected to one or more interconnect structures formed in the third level on the frontside (e.g., an interconnect structure configured as the WWL for the second memory cell 100, which is formed based on the layout 400).

Referring next to FIG. 4, the layout 400 can include patterns for forming interconnect structures 410, 420, 430, 440, 450, and 460 in the third level on the frontside, respectively. The third level, disposed over the second level formed based on the layout 300 (FIG. 3), may sometimes be referred to as a bottommost one of plural frontside metallization layers, e.g., M0 layer, and the interconnect structures 410 to 460 disposed therein are each sometimes referred to as an M0 track. The frontside metallization layer typically includes one or more dielectric materials (e.g., silicon, oxide, a low-k dielectric material, or the like) embedding the corresponding metal tracks formed of, e.g., copper. These M0 tracks can extend along the same direction as the active regions 210-220 and 310-320, e.g., the X-direction.

In some embodiments, the M0 tracks 410 to 440 can each be coupled to a corresponding one of the underlying MDs through a VD or a corresponding one of the underlying gate structures (gate sections) in the second level through VG. For example, the M0 track 410 is coupled to the gate sections 330A and 335A through the VG 380 and 381, respectively; the M0 track 420 is coupled to the MD 350 through the VD 370; the M0 track 430 is coupled to the MD 354 through the VD 371; the 440 is coupled to the gate sections 330B and 335B through the VG 382 and 383, respectively; the M0 track 450 is coupled to the MD 358 through the VD 373; and the M0 track 460 is coupled to the MD 364 through the VD 372.

The M0 track 410 can operatively serve as a part of the WWL for the first memory cell 100; the M0 track 420 can operatively serve as a part of the WBL for the first and second memory cells 100; the M0 track 430 can operatively serve a part of a power rail carrying the ground voltage VSS for the first memory cell 100; the M0 track 440 can operatively serve as a part of the WWL for the second memory cell 100; the M0 track 450 can operatively serve as a part of the WBLB for the first and second memory cells 100; and the M0 track 460 can operatively serve as a part of a power rail carrying the ground voltage VSS for the second memory cell 100.

Referring then to FIG. 5, the layout 500 can include patterns for forming interconnect structures 510, 520, 530, 535, 540, 550, 560, and 565 in the first level on the backside, respectively. The first level, disposed on the backside, may sometimes be referred to as a bottommost one of plural backside metallization layers, e.g., BM0 layer, and the interconnect structures 510 to 565 disposed therein are each sometimes referred to as a BM0 track. The backside metallization layer typically includes one or more dielectric materials (e.g., silicon, oxide, a low-k dielectric material, or the like) embedding the corresponding metal tracks formed of, e.g., copper. These BM0 tracks can extend along the same direction as the active regions 210-220 and 310-320, e.g., the X-direction.

In some embodiments, the BM0 tracks 510 to 565 can each be coupled to a corresponding one of the overlaying MDs in the first level on the frontside through a BVD or a corresponding one of the overlying gate structures (gate sections) in the first level on the frontside through a BVG. For example, the BM0 track 510 is coupled to the MD 254 through the BVD 271; the BM0 track 540 is coupled to the MD 250 through the BVD 273; the BM0 track 520 is coupled to the gate section 230A through the BVG 280; the BM0 track 550 is couped to the gate section 230B through the BVG 283; the BM0 track 530 is coupled to the MD 252 and the gate section 240A through the BVD 270 and the BVG 282, respectively; the BM0 track 535 is coupled to the MD 256 and the gate section 235A through the BVD 272 and the BVG 281, respectively; the BM0 track 560 is coupled to the MD 262 and the gate section 240B through the BVD 274 and the BVG 285, respectively; and the BM0 track 565 is coupled to the MD 266 and the gate section 235B through the BVD 275 and the BVG 284, respectively.

The BM0 track 510 can operatively serve a part of a power rail carrying the supply voltage VDD for the first and second memory cells 100; the BM0 track 540 can operatively serve as a part of the RBL for the first and second memory cells 100; the BM0 track 520 can operatively serve as a part of the RWL for the first memory cell 100; and the BM0 track 550 can operatively serve as a part of the RWL for the second memory cell 100. Further, the BM0 track 530 and 535 can serve as the above-mentioned first and second internal contact structures for the first memory cell 100, respectively; and the BM0 track 560 and 565 can serve as the above-mentioned first and second internal contact structures for the second memory cell 100, respectively.

The layout 600 of FIG. 6 is substantially similar to the layout 400 of FIG. 4, except that some of the configured functionality is different, and the layout 700 of FIG. 7 is substantially similar to the layout 500 of FIG. 5. Thus, the following discussion will be focused on the difference. For example, the layout 600 also includes the M0 tracks 410 to 460. However, the M0 track 420 is configured as the VSS for the first memory cell, the M0 track 430 is configured as the WBL for both the first and second memory cells, the M0 track 450 is configured as the VSS for the second memory cell, and the M0 track 460 is configured as the WBLB for both the first and second memory cells. The layout 700 is identical to the layout 500 (e.g., also including the BM0 tracks 510, 520, 530, 535, 540, 550, 560, and 565 configured as the VDD for both the first and second memory cells, the RWL of the first memory cell, the first internal contact structure of the first memory cell, the second internal contact structure of the first memory cell, the RBL for both the first and second memory cells, the RWL of the second memory cell, the first internal contact structure of the second memory cell, the second internal contact structure of the second memory cell, respectively).

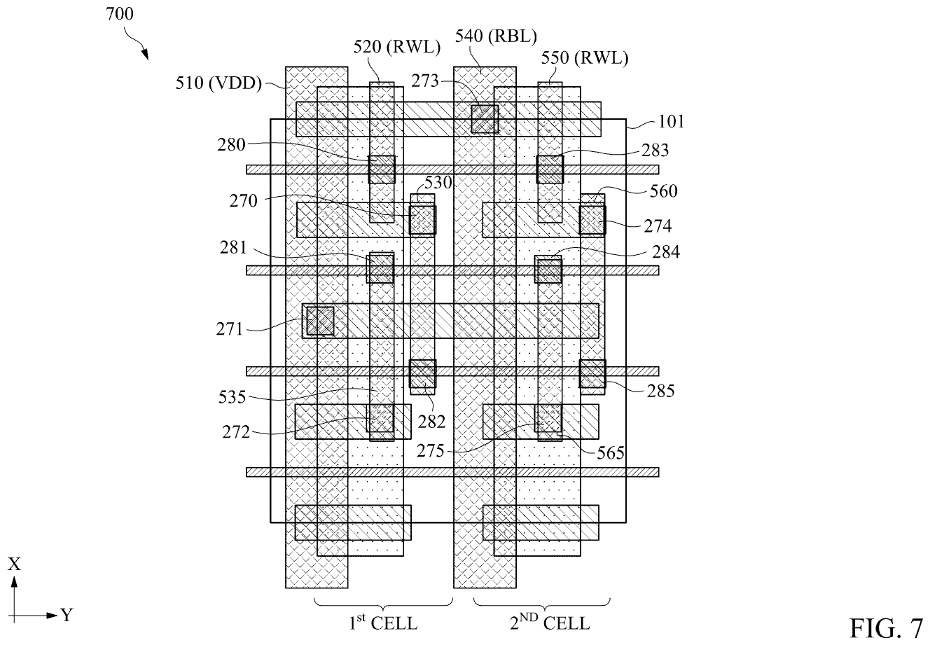

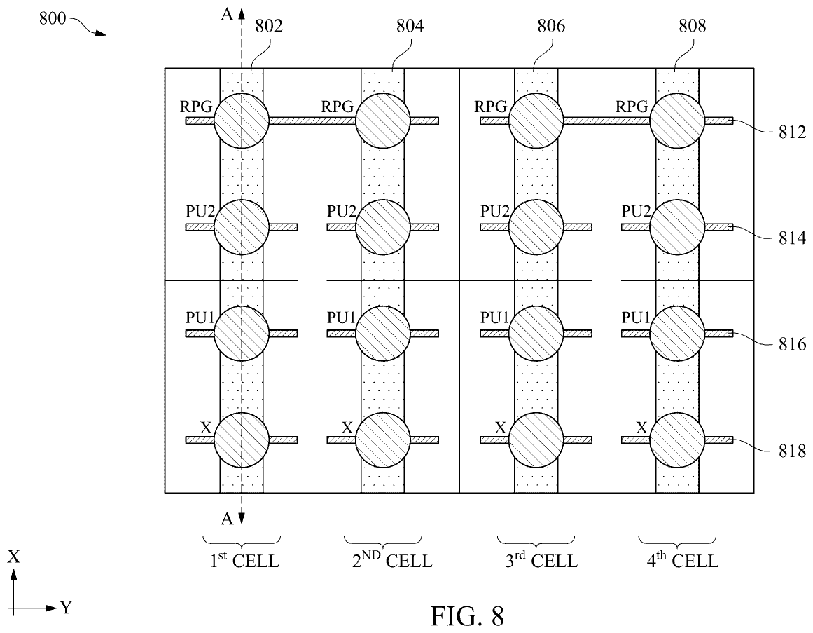

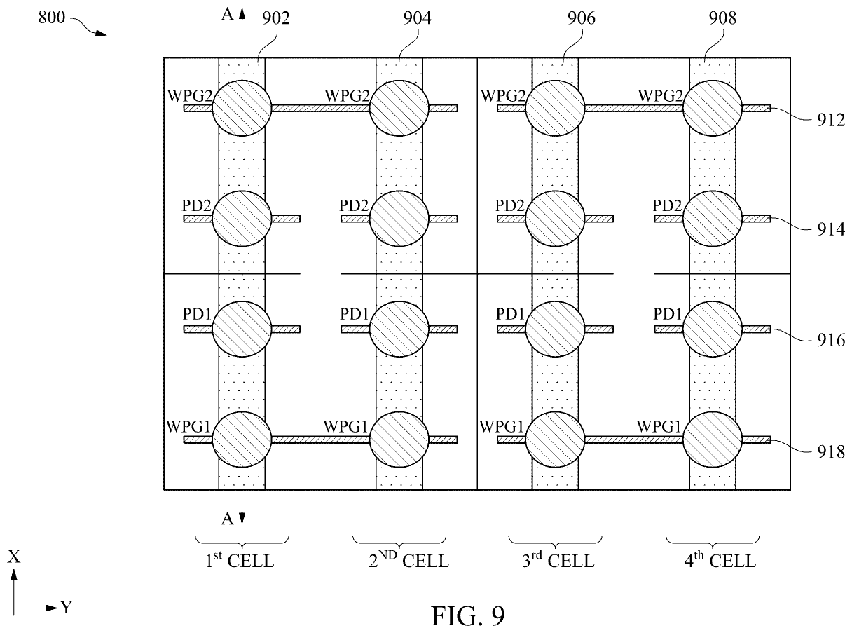

FIG. 8 and FIG. 9 collectively illustrate an example map 800 of a memory array including a plural number of the memory cells 100, in accordance with some embodiments. For example, the memory array can include four memory cells 100 (1st memory cell, 2nd memory cell, 3rd memory cell, and 4th memory cell, as indicated). Particularly, FIG. 8 illustrates a first level of the map 800 (similar to the layout 200 of FIG. 2), and FIG. 9 illustrates a second, higher level of the map 800 (similar to the layout 300 of FIG. 3), where the first and second levels can be vertically aligned with each other.

Solely for purposes of simplicity, FIG. 8 and FIG. 9 illustrate respective active regions (e.g., active regions 802, 804, 806, and 808 of FIG. 8, and active regions 902, 904, 906, and 908 of FIG. 9) and gate structures (e.g., gate structures 812, 814, 816, and 818 of FIG. 8, and gate structures 912, 914, 916, and 918 of FIG. 9) of the seven transistors of each of the four memory cells, but are not intended to limit the scope of the present disclosure. As shown, in FIG. 8, the respective transistors RPGs of two or more of the memory cells may share the same gate structure, for example, the transistors RPGs of the first and second memory cells sharing a first section of the gate structure 812, and the transistors RPGs of the third and fourth memory cells sharing a second section of the gate structure 812. Similarly, in FIG. 9, the respective transistors WPG1s of two or more of the memory cells may share the same gate structure, and the respective transistors WPG2s of two or more of the memory cells may share the same gate structure. In some embodiments, these four memory cells may be operatively arranged along one common row (e.g., one WL), and along respective four columns (e.g., four pairs of BL/BLB).

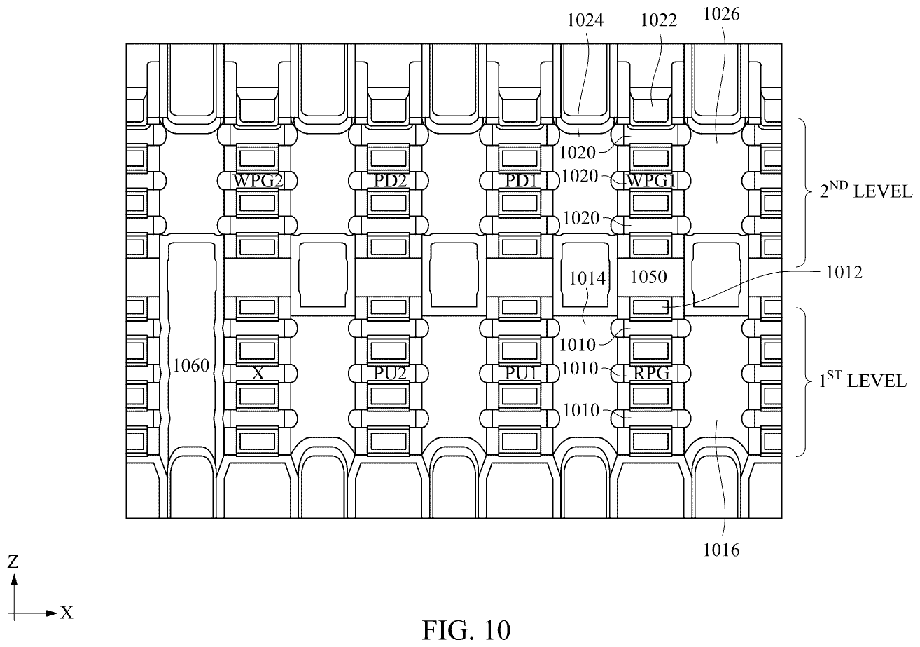

FIG. 10 illustrates a cross-sectional view of a portion of a semiconductor device formed based on the map 800 (FIGS. 8-9), in accordance with some embodiments. For example, the cross-sectional view of FIG. 10 is cut along line A-A, as indicated in FIGS. 8-9. Specifically, the line A-A extends along the active region 802 of FIG. 8 and active region 902 of FIG. 9, or cut along the first memory cell.

As depicted, the transistors PU2, PU1, and RPG are formed in the first level on the frontside of a substrate, and the transistors WPG2, PD2, PD1, and WPG1 are formed in the second level over the first level. The transistors PD2 and PU2 are vertically aligned with each other; the transistors PD1 and PUI are vertically aligned with each other; the transistors WPG1 and RPG are vertically aligned with each other; and the transistor WPG2 and the dummy transistor are vertically aligned with each other.

In some embodiments, the transistors PU2, PU1, and RPG are formed with p-type, by each having its source/drain terminals formed as p-type epitaxial structures and its gate terminal (or active gate structure) formed with one or more p-type work function metals; and the transistors WPG2, PD2, PD1, and WPG1 are formed with n-type, by each having its source/drain terminals formed as n-type epitaxial structures and its gate terminal (or active gate structure) formed with one or more n-type work function metals.

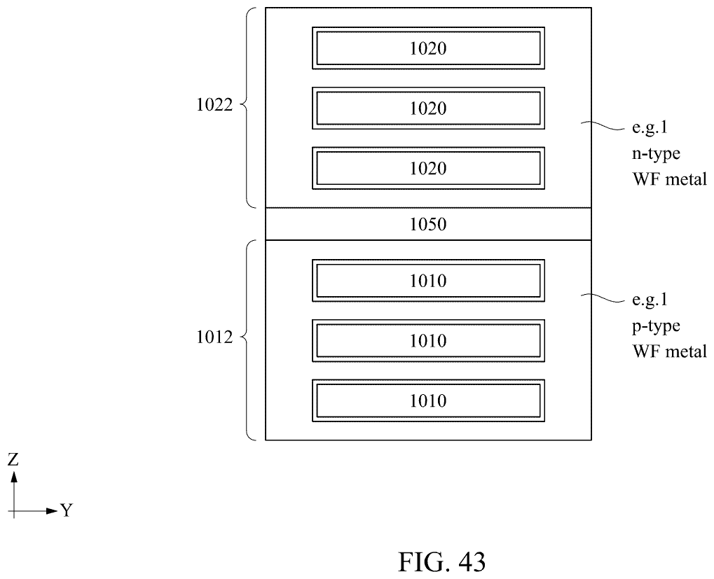

Using the vertically aligned transistor RPG and transistor WPG1 as a representative example, the transistor RPG has a number of nanosheets 1010 operatively configured as its channel, p-type epitaxial structures 1014 and 1016 operatively configured as its source/drain terminals, and gate structure 1012 operatively configured as its gate terminal; and the transistor WPG1 has a number of nanosheets 1020 operatively configured as its channel, n-type epitaxial structures 1024 and 1026 operatively configured as its source/drain terminals, and gate structure 1022 operatively configured as its gate terminal. Each of the nanosheets 1010 is wrapped by the gate structure 1012 that can include a gate dielectric and one or more p-type work function metals, and has its ends coupled to the p-type epitaxial structures 1014 and 1016, respectively. Each of the nanosheets 1020 is wrapped by the gate structure 1022 that can include a gate dielectric and one or more n-type work function metals, and has its ends coupled to the n-type epitaxial structures 1024 and 1026, respectively. The gate structure 1012 and the gate structure 1022 are electrically isolated from each other with a dielectric layer 1050, in accordance with some embodiments. For example, in another cross-sectional view (e.g., FIG. 43) perpendicular to the cross-sectional view of FIG. 10, the gate structure 1012 (or its one or more work function metals) and the gate structure 1022 (or its one or more work function metals) are separated from each other by the dielectric layer 1050. Stated another way, the work function metals of the gate structure 1012 and the work function metals of the gate structure 1022 are not in contact with each other. Further, one of the source/drain terminals of the dummy transistor (X) may be replaced with a dielectric structure 1060, to which one end of each nanosheet of the dummy transistor is coupled.

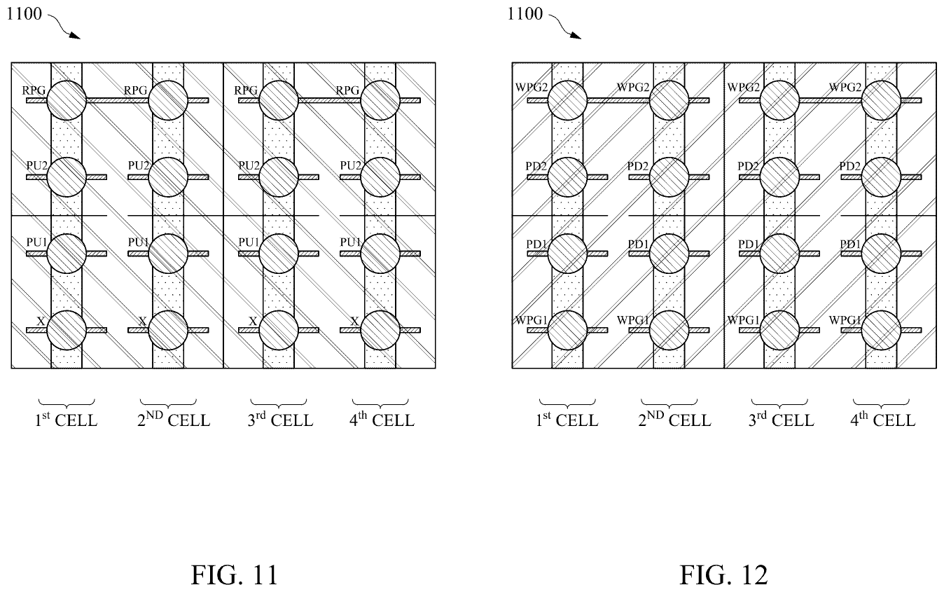

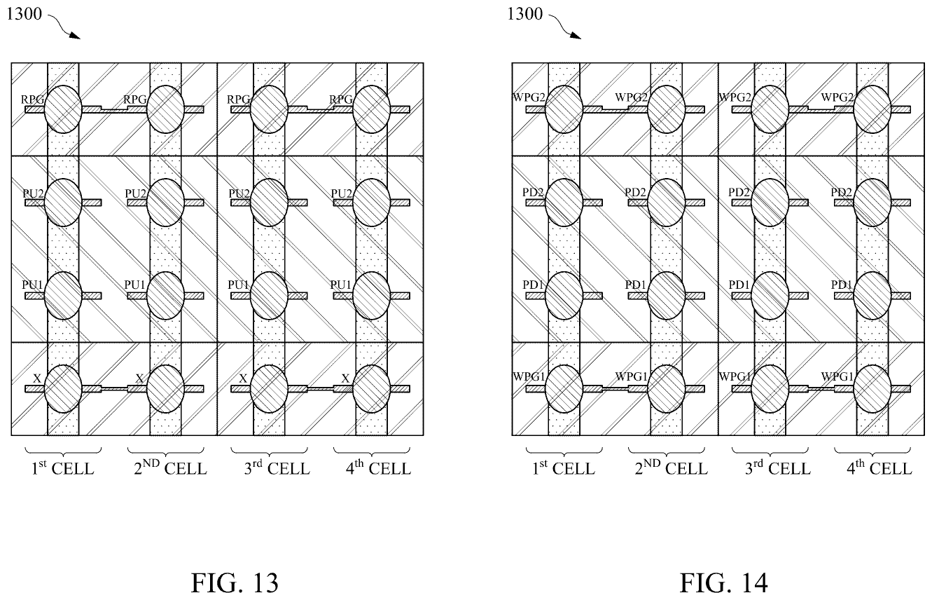

FIG. 11 and FIG. 12 collectively illustrate an example map 1100, and FIG. 13 and FIG. 14 collectively illustrate another example map 1300, in accordance with some embodiments. Each of the maps 1100 and 1300 is similar to the map 800 shown in FIGS. 8-9, e.g., a memory array including four of the memory cells 100 arranged along one common row (or WL).

In some embodiments, the map 1100 illustrates that the transistors RPG, PU2, and PU1 of each of the four memory cells have their gate structures formed with a first combination of work function metals, or with a first threshold voltage (FIG. 11); and the transistors WPG2, PD2, PD1, and WPG1 of each of the four memory cells have their gate structures formed with a second combination of work function metals, or with a second threshold voltage (FIG. 12).

In some embodiments, the map 1300 illustrates that the transistors PU2 and PU1 of each of the four memory cells have their gate structures formed with a first combination of work function metals, or with a first threshold voltage (FIG. 13); the transistors RPG and the dummy transistor of each of the four memory cells have their gate structures formed with a second combination of work function metals, or with a second threshold voltage (FIG. 13); the transistors PD2 and PD1 of each of the four memory cells have their gate structures formed with a third combination of work function metals, or with a third threshold voltage (FIG. 14); and the transistors WPG1 and WPG2 of each of the four memory cells have their gate structures formed with a fourth combination of work function metals, or with a fourth threshold voltage (FIG. 14).

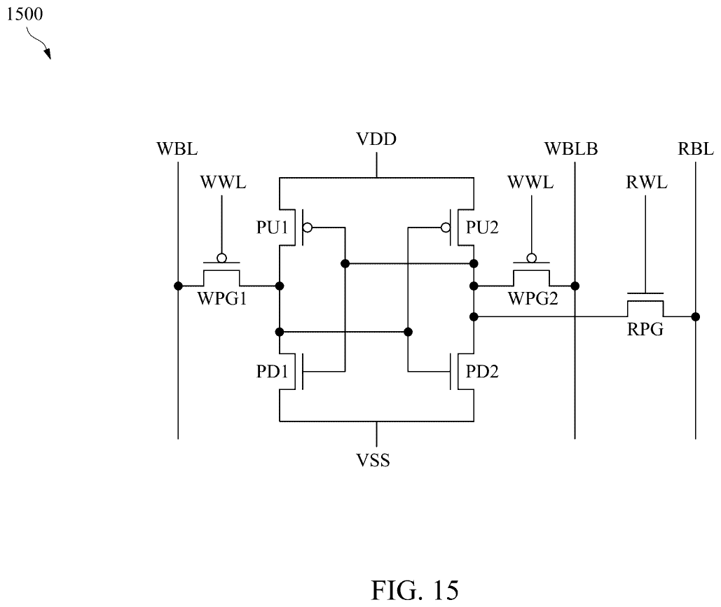

FIG. 15 illustrates another example circuit diagram of a memory cell 1500 including seven transistors that operatively form a 7T SRAM cell, in accordance with some embodiments. The memory cell 1500 is similar to the memory cell 100 (e.g., including a first pull-up transistor PU1, a second pull-up transistor PU2, a first pull-down transistor PD1, a second pull-down transistor PD2, a first write pass-gate transistor WPG1, a second write pass-gate transistor WPG2, and a read pass-gate transistor RPG), except that the memory cell 1500 has its transistors WPG1 and WPG2 configured with p-type and transistor RPG configured with n-type.

In some embodiments, these seven transistors can be physically formed with the above-discussed CFET structure. For example, the transistors PU1, PU2, WPG1, and WPG2 can formed at a first frontside level, and the transistors PD1, PD2, and RPG can be formed at a second frontside level over the first frontside level. Specifically, the transistors PD1 and PU1 are vertically aligned with each other; the transistors PD2 and PU2 are vertically aligned with each other; and the transistor RPG is vertically aligned with one of the transistor WPG1 or WPG2.

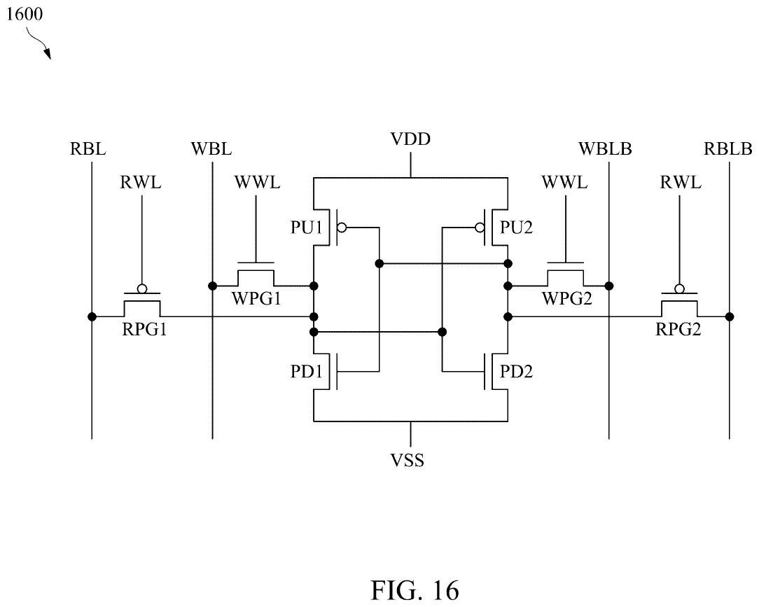

FIG. 16 illustrates an example circuit diagram of a memory cell 1600 including eight transistors that operatively form an 8T SRAM cell, in accordance with some embodiments. The memory cell 1600 includes a first pull-up transistor PU1, a second pull-up transistor PU2, a first pull-down transistor PD1, a second pull-down transistor PD2, a first write pass-gate transistor WPG1, a second write pass-gate transistor WPG2, a first read pass-gate transistor RPG1, and a second read pass-gate transistor RPG2.

In some embodiments, the memory cell 1600 has its transistors PU1, PU2, RPG1, and RPG2 configured with p-type, and transistors PD1, PD2, WPG1, and WPG2 configured with n-type. These eight transistors can be physically formed with the above-discussed CFET structure. For example, the transistors PU1, PU2, RPG1, and RPG2 can formed at a first frontside level, and the transistors PD1, PD2, WPG1, and WPG2 can be formed at a second frontside level over the first frontside level. Specifically, the transistors PD1 and PUI are vertically aligned with each other; the transistors PD2 and PU2 are vertically aligned with each other; the transistors RPG1 and WPG1 are vertically aligned with each other; and the transistors RPG2 and WPG2 are vertically aligned with each other.

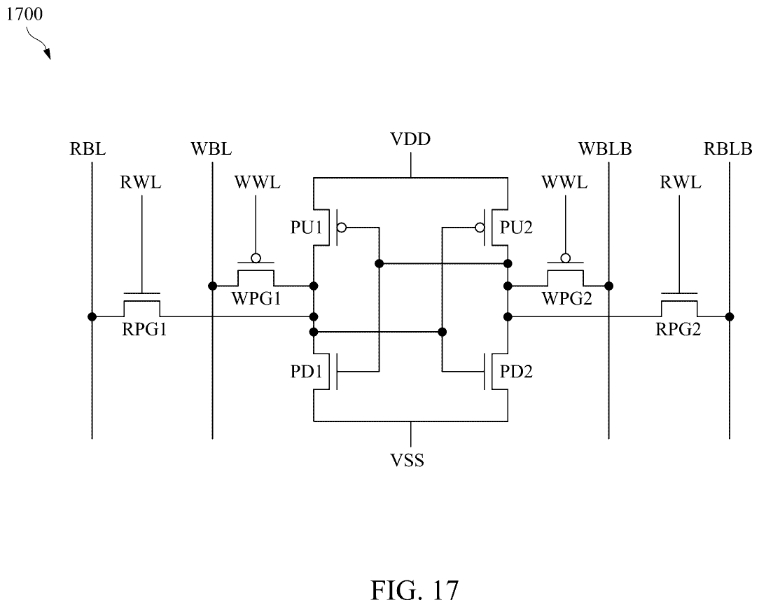

FIG. 17 illustrates another example circuit diagram of a memory cell 1700 including eight transistors that operatively form an 8T SRAM cell, in accordance with some embodiments. The memory cell 1700 includes a first pull-up transistor PU1, a second pull-up transistor PU2, a first pull-down transistor PD1, a second pull-down transistor PD2, a first write pass-gate transistor WPG1, a second write pass-gate transistor WPG2, a first read pass-gate transistor RPG1, and a second read pass-gate transistor RPG2.

In some embodiments, the memory cell 1700 has its transistors PU1, PU2, WPG1, and WPG2 configured with p-type, and transistors PD1, PD2, RPG1, and RPG2 configured with n-type. These eight transistors can be physically formed with the above-discussed CFET structure. For example, the transistors PU1, PU2, WPG1, and WPG2 can formed at a first frontside level, and the transistors PD1, PD2, RPG1, and RPG2 can be formed at a second frontside level over the first frontside level. Specifically, the transistors PD1 and PU1 are vertically aligned with each other; the transistors PD2 and PU2 are vertically aligned with each other; the transistors RPG1 and WPG1 are vertically aligned with each other; and the transistors RPG2 and WPG2 are vertically aligned with each other.

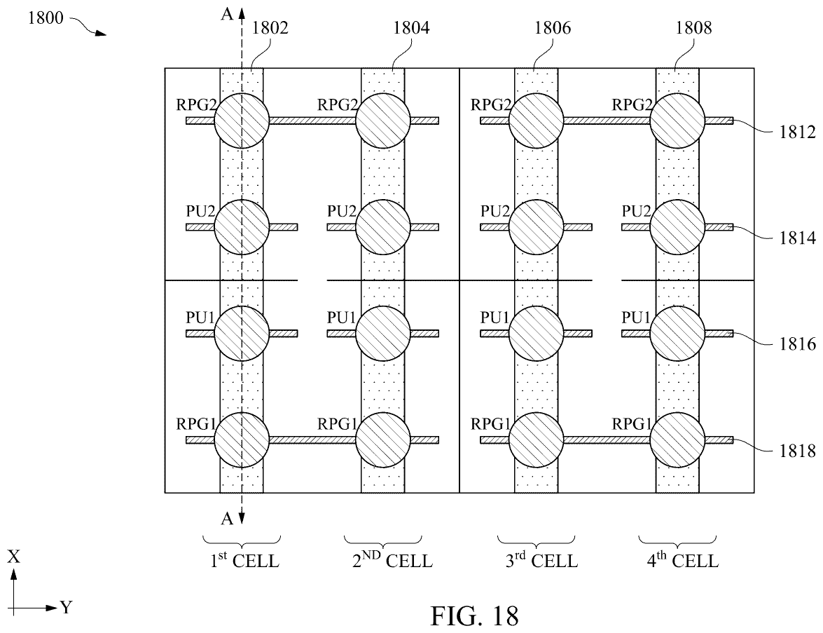

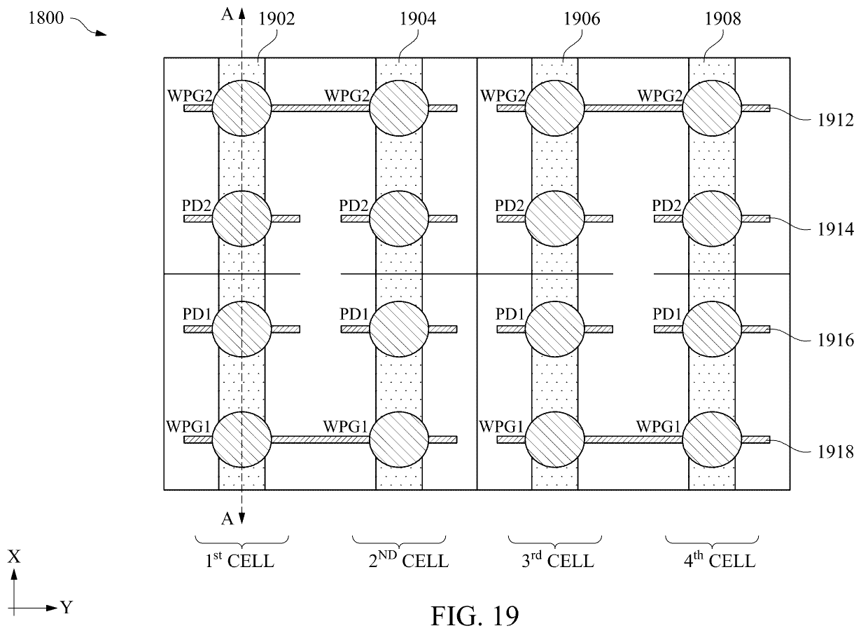

FIG. 18 and FIG. 19 collectively illustrate an example map 1800 of a memory array including a plural number of the memory cells 1600, in accordance with some embodiments. For example, the memory array can include four memory cells 1600 (1^{st} memory cell, 2^{nd} memory cell, 3^{rd} memory cell, and 4^{th} memory cell, as indicated). Particularly, FIG. 18 illustrates a first level of the map 1800 (configured to form the respective transistors RPG1, RPG2, PU1, and PU2 of the first to fourth memory cells 1600), and FIG. 19 illustrates a second, higher level of the map 1800 (configured to form the respective transistors WPG1, WPG2, PD1, and PD2 of the first to fourth memory cells 1600), where the first and second levels can be vertically aligned with each other.

Solely for purposes of simplicity, FIG. 18 and FIG. 19 illustrate respective active regions (e.g., active regions 1802, 1804, 1806, and 1808 of FIG. 18, and active regions 1902, 1904, 1906, and 1908 of FIG. 19) and gate structures (e.g., gate structures 1812, 1814, 1816, and 1818 of FIG. 18, and gate structures 1912, 1914, 1916, and 1918 of FIG. 19) of the eight transistors of each of the four memory cells 1600, but are not intended to limit the scope of the present disclosure. As shown, in FIG. 18, the respective transistors RPG1s and/or RPG2s of two or more of the memory cells may share the same gate structure, for example, the transistors RPG1s of the first and second memory cells sharing a first section of the gate structure 1812, and the transistors RPG1s of the third and fourth memory cells sharing a second section of the gate structure 1812. Similarly, in FIG. 19, the respective transistors WPG1s and/or WPG2s of two or more of the memory cells may share the same gate structure. In some embodiments, these four memory cells may be operatively arranged along one common row (e.g., one WL), and along respective four columns (e.g., four pairs of BL/BLB).

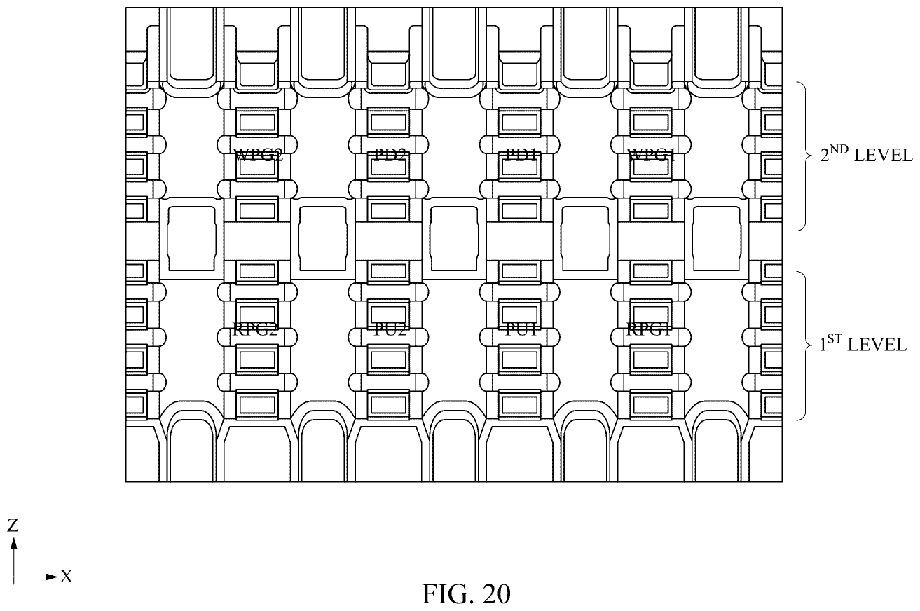

FIG. 20 illustrates a cross-sectional view of a portion of a semiconductor device formed based on the map 1800 (FIGS. 18-19), in accordance with some embodiments. For example, the cross-sectional view of FIG. 20 is cut along line A-A, as indicated in FIGS. 18-19. Specifically, the line A-A extends along the active region 1802 of FIG. 18 and active region 1902 of FIG. 19, or cut along the first memory cell.

As depicted, the transistors PU2, PU1, RPG2, and RPG1 are formed in the first level on the frontside of a substrate, and the transistors WPG2, PD2, PD1, and WPG1 are formed in the second level over the first level. The transistors PD2 and PU2 are vertically aligned with each other; the transistors PD1 and PU1 are vertically aligned with each other; the transistors WPG1 and RPG1 are vertically aligned with each other; and the transistor WPG2 and the transistor RPG2 are vertically aligned with each other. In some embodiments, the transistors PU2, PU1, RPG2, and RPG1 are formed with p-type, by each having its source/drain terminals formed as p-type epitaxial structures and its gate terminal (or active gate structure) formed with one or more p-type work function metals; and the transistors WPG2, PD2, PD1, and WPG1 are formed with n-type, by each having its source/drain terminals formed as n-type epitaxial structures and its gate terminal (or active gate structure) formed with one or more n-type work function metals.

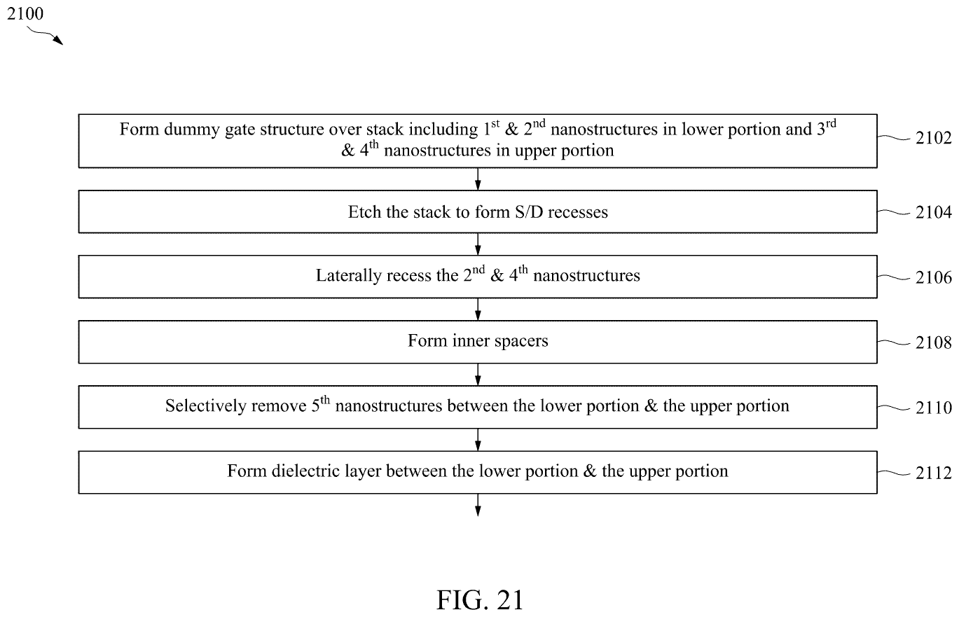

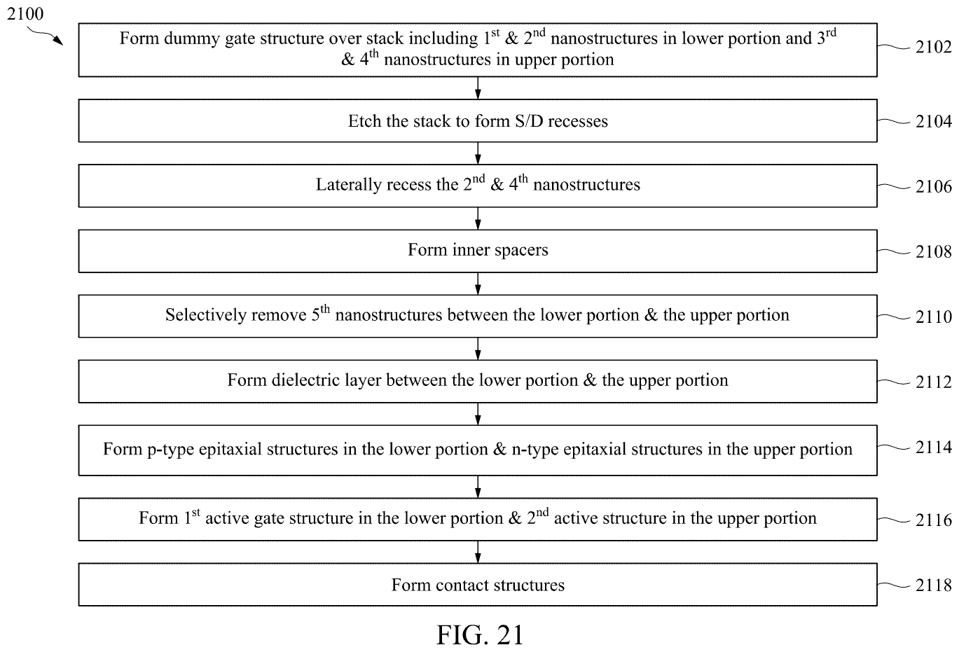

FIG. 21 illustrates a flow chart of an example method 2100 for forming a memory cell configured in a CFET structure, according to some embodiments of the present disclosure. For example, at least some of the operations (or steps) of the method 2100 can be used to form the memory cell 100 (FIG. 1), the memory cell 1500 (FIG. 15), the memory cell 1600 (FIG. 16), or the memory cell 1700 (FIG. 17) in the CFET structure, which includes a number of p-type transistors disposed at the first level on the frontside of a substrate and a number of n-type transistors disposed at the second, upper level on the frontside of the substrate.

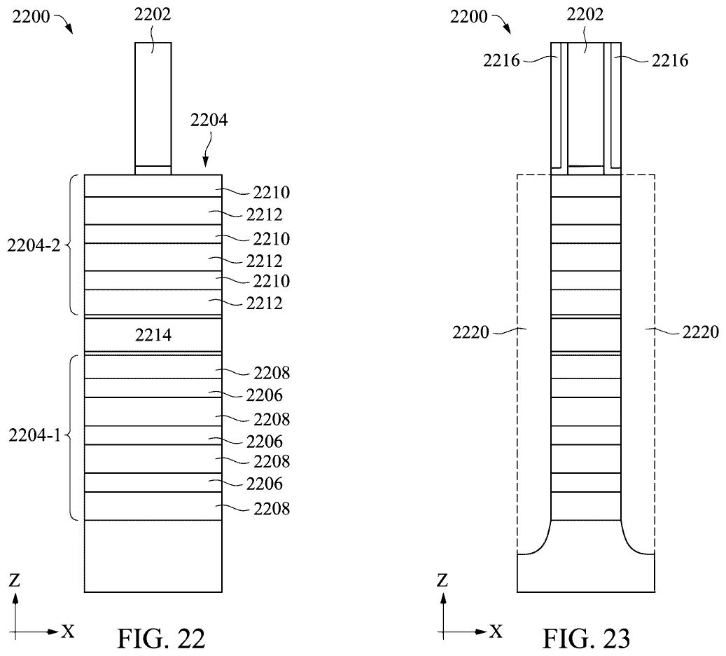

It should be appreciated that the method 2100 is merely an example, and is not intended to limit the present disclosure. Accordingly, it is understood that additional operations may be provided before, during, and after the method 2100 of FIG. 21, and that some other operations may only be briefly described herein. In some embodiments, operations of the method 2100 may be associated with cross-sectional views of a CFET structure 2200 at various fabrication stages as shown in FIGS. 22, 23, 24, 25, 26, 27, 28, 29, and 30, respectively, which will be discussed in further detail below.

As a brief overview, the method 2100 starts with operation 2102 of forming a number of dummy gate structures over a stack including a lower portion and an upper portion. The lower portion includes a number of first nanostructures and a number of second nanostructures alternately stacked on top of one another, and the upper portion includes a number of third nanostructures and a number of fourth nanostructures alternately stacked on top of one another. The first and third nanostructures may be formed of a first semiconductor material, and the second and fourth nanostructures may be formed of a second semiconductor material. Further, the lower portion and the upper portion may be separated from each other with a fifth nanostructure formed of a third semiconductor material. The method 2100 continues to operation 2104 of etching the stack to form source/drain recesses. The method 2100 continues to operation 2106 of laterally recessing the second nanostructures and the fourth nanostructures. The method 2100 continues to operation 2108 of forming a number of inner spacers. The method 2100 continues to operation 2110 of selectively removing the fifth nanostructure. The method 2100 continues to operation 2112 of forming a dielectric layer between the lower portion and the upper portion. The method 2100 continues to operation 2114 of forming a number of p-type epitaxial structures in the lower portion and a number of n-type epitaxial structures in the upper portion. The method 2100 continues to operation 2116 of forming a first active gate structure in the lower portion and a second active gate structure in the upper portion. The method 2100 continues to operation 2118 of forming a number of connection structures.

Corresponding to operation 2102 of FIG. 21, FIG. 22 is a cross-sectional view of the CFET structure 2200 including a number of dummy gate structures 2202 over a stack 2204, at one of the various stages of fabrication. The cross-sectional view of FIG. 22 is cut along the lengthwise direction of an active region of the CFET structure 2200 (e.g., the X-direction illustrated above).

In some embodiments, the stack 2204 may be formed over a semiconductor substrate 2201, followed by the dummy gate structure 2202 formed over the stack 2204. The stack 2204 can extend along the X-direction, and the dummy gate structure 2202 can extend along the Y-direction to straddle or otherwise traverse the stack 2204. The stack 2204 includes a lower portion 2204-1 and an upper portion 2204-2, which can correspond to the first level and the second level on the frontside of the substrate, respectively. The lower portion 2204-1 includes a number of first nanostructures 2206 and a number of second nanostructures 2208 alternately stacked on top of one another, and the upper portion 2204-2 includes a number of third nanostructures 2210 and a number of fourth nanostructures 2212 alternately stacked on top of one another.

The substrate 2201, the first nanostructures 2206, and the third nanostructures 2210 may be formed of a first semiconductor material, e.g., silicon (Si), while the second nanostructures 2208 and the fourth nanostructures 2212 may be formed of a second semiconductor material, e.g., silicon germanium (Si₁₋ₓGeₓ). Further, the lower portion 2204-1 and the upper portion 2204-2 are separated from each other with a fifth nanostructure 2214 formed of a third semiconductor material, e.g., silicon germanium (Si_{1-y}Ge_{y}). In some embodiments, the molar ratio “x” of the second semiconductor material may be less than 0.5, and the molar ratio “y”of the third semiconductor material may be higher than 0.5.

The nanostructures 2206 to 2212 can be epitaxially grown from the semiconductor substrate 2201. For example, each of the nanostructures 2206 to 2212 may be grown by a molecular beam epitaxy (MBE) process, a chemical vapor deposition (CVD) process such as a metal organic CVD (MOCVD) process, and/or other suitable epitaxial growth processes. Upon growing the nanostructures 2206 to 2212 on the substrate 2201 as a blanket stack, the blanket stack may be patterned to form the stack 2204 shown in FIG. 22 (e.g., having a lengthwise direction in the X-direction and a relatively narrow width in the Y-direction). After the stack 2204 is formed, the dummy gate structure 2202, including a dummy gate dielectric (e.g., silicon oxide) and a dummy gate material (e.g., polysilicon), is formed to straddle the stack 2204.

Corresponding to operation 2104 of FIG. 21, FIG. 23 is a cross-sectional view of the CFET structure 2200 in which source/drain recesses 2220 are formed, at one of the various stages of fabrication. The cross-sectional view of FIG. 23 is cut along the lengthwise direction of an active region of the CFET structure 2200 (e.g., the X-direction illustrated above).

To form the source/drain recesses 2220, a pair of gate spacers 2216 may be formed on opposite sidewalls of the dummy gate structure 2202. Next, with the dummy gate structure 2202 and the gate spacers 2216 serving as a mask, the stack 2204 is again patterned to form the source/drain recesses 2220 using an anisotropic etching process. Such an anisotropic etching process can include reactive ion etch (RIE), neutral beam etch (NBE), the like, or combinations thereof.

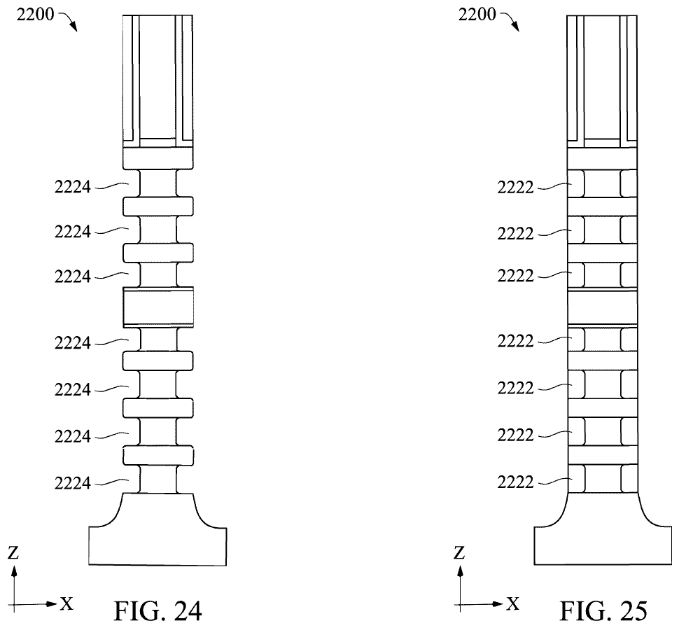

Corresponding to operation 2106 of FIG. 21, FIG. 24 is a cross-sectional view of the CFET structure 2200 in which the second nanostructures 2208 and the fourth nanostructures 2212 are laterally recessed, at one of the various stages of fabrication. The cross-sectional view of FIG. 24 is cut along the lengthwise direction of an active region of the CFET structure 2200 (e.g., the X-direction illustrated above).

As shown, respective end portions of each of the second nanostructures 2208 and the fourth nanostructures 2212 (formed of Si₁₋ₓGeₓ) are removed (e.g., etched) using a “pull-back” process to pull each of the nanostructures 2208 and 2212 back by a pull-back distance. For example, the pull-back process may include a hydrogen chloride (HCl) gas isotropic etching process, which etches SiGe with the lower Ge composition (e.g., Si₁₋ₓGeₓ) without attacking Si or SiGe with the higher Ge composition (e.g., Si_{1-y}Ge_{y}). As such, the nanostructures 2206 (Si), 2210 (Si), and 2214 (Si_{1-y}Ge_{y}) may remain substantially intact during this process, and a number of recess 2224, each inwardly extending from the source/drain recess 2220, can be formed.

Corresponding to operation 2108 of FIG. 21, FIG. 25 is a cross-sectional view of the CFET structure 2200 including a number of inner spacers 2222, at one of the various stages of fabrication. The cross-sectional view of FIG. 25 is cut along the lengthwise direction of an active region of the CFET structure 2200 (e.g., the X-direction illustrated above).

The inner spacers 2222 can be formed by filling the recesses 2224 with a dielectric material. For example, the inner spacers 2222 can be deposited using, e.g., a conformal deposition process and subsequent isotropic or anisotropic etch back to remove excess spacer material on the sidewalls of the stack 2204. The dielectric material, used to form the inner spacer 2222, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

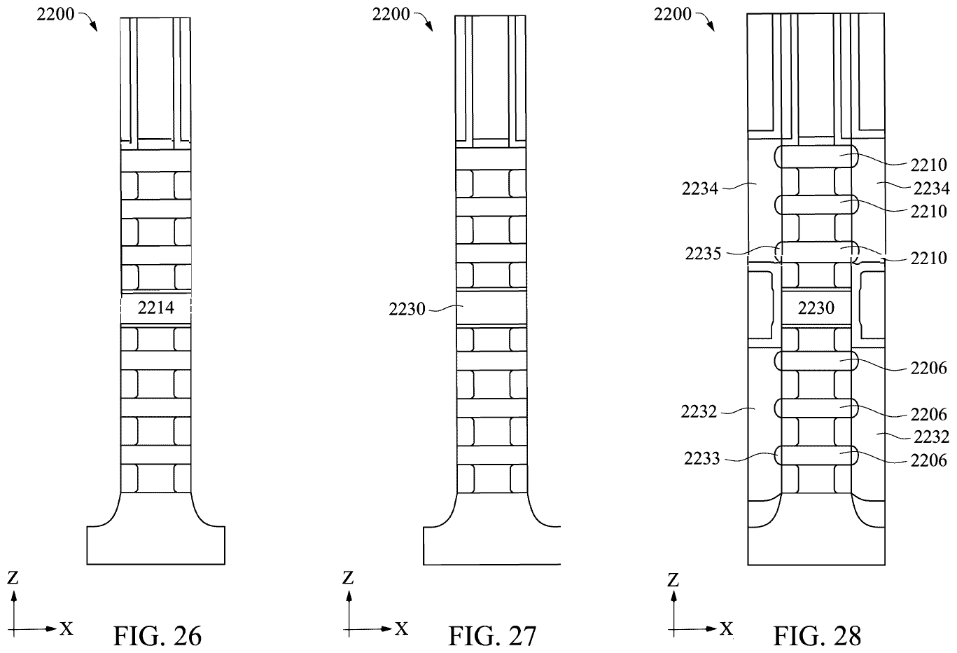

Corresponding to operation 2110 of FIG. 21, FIG. 26 is a cross-sectional view of the CFET structure 2200 in which the fifth nanostructure 2214 is removed, at one of the various stages of fabrication. The cross-sectional view of FIG. 26 is cut along the lengthwise direction of an active region of the CFET structure 2200 (e.g., the X-direction illustrated above).

After forming the inner spacers 2222, the fifth nanostructure 2214 can be selectively removed using an isotropic etching process that etches Si_{1-y}Ge_{y} without attacking Si. As such, the first nanostructures 2206 (Si) and third nanostructures 2210 (Si) can remain substantially intact, the fifth nanostructure 2214 (Si_{1-y}Ge_{y}) can be completely removed, and the remaining portions of the second nanostructures 2208 (Si₁₋ₓGeₓ) and fourth nanostructures 2212 (Si₁₋ₓGeₓ) can remain with the protection of the inner spacers 2222.

Corresponding to operation 2112 of FIG. 21, FIG. 27 is a cross-sectional view of the CFET structure 2200 including a dielectric layer 2230, at one of the various stages of fabrication. The cross-sectional view of FIG. 27 is cut along the lengthwise direction of an active region of the CFET structure 2200 (e.g., the X-direction illustrated above).

After the fifth nanostructure 2214 is removed, a space is formed between the lower portion 2204-1 and the upper portion 2204-2. The dielectric layer 2230 can be formed by filling the space with a dielectric material. The dielectric material, used to form the dielectric layer 2230, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating structure for transistors.

Corresponding to operation 2114 of FIG. 21, FIG. 28 is a cross-sectional view of the CFET structure 2200 including a number of first epitaxial structures 2232 and a number of second epitaxial structures 2234, at one of the various stages of fabrication. The cross-sectional view of FIG. 28 is cut along the lengthwise direction of an active region of the CFET structure 2200 (e.g., the X-direction illustrated above).

As shown, a pair of the first epitaxial structure 2232 are coupled to ends of each of the first nanostructures 2206, respectively; and a pair of the second epitaxial structure 2234 are coupled to ends of each of the third nanostructures 2210, respectively. The first epitaxial structures 2232 can be formed through a first epitaxial growth process, followed by a second epitaxial growth process for forming the second epitaxial structures 2234. Further, between the first epitaxial growth process and the second epitaxial growth process, one or more dielectric layers 2236 can be formed to electrically isolate the first epitaxial structures 2232 and the second epitaxial structures 2234. Each of the first epitaxial growth process and the second epitaxial growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. Specifically, the first epitaxial structures 2232 can be grown from the first nanostructures 2206, and the second epitaxial structures 2234 can be grown from the third nanostructures 2210.

The first epitaxial structures 2232 and the second epitaxial structures 2234 may each include silicon germanium (SiGe), indium arsenide (InAs), indium gallium arsenide (InGaAs), indium antimonide (InSb), gallium arsenide (GaAs), gallium antimonide (GaSb), indium aluminum phosphide (InAlP), indium phosphide (InP), any other suitable material, or combinations thereof. Further, in-situ doping (ISD) may be applied during the formation of each of the first epitaxial structures 2232 and the second epitaxial structures 2234. For example, the first epitaxial structures 2232 can be doped by implanting p-type dopants, e.g., boron (B), etc., into them; and the second epitaxial structures 2234 can be doped by implanting n-type dopants, e.g., arsenic (As), phosphorous (P), etc., into them. In some embodiments, the first epitaxial structure 2232 can be coupled to each of the first nanostructures 2206 through a lightly doped region 2233 (e.g., SiGeB); and the second epitaxial structure 2234 can be coupled to each of the third nanostructures 2210 through a lightly doped region 2235 (e.g., SiP).

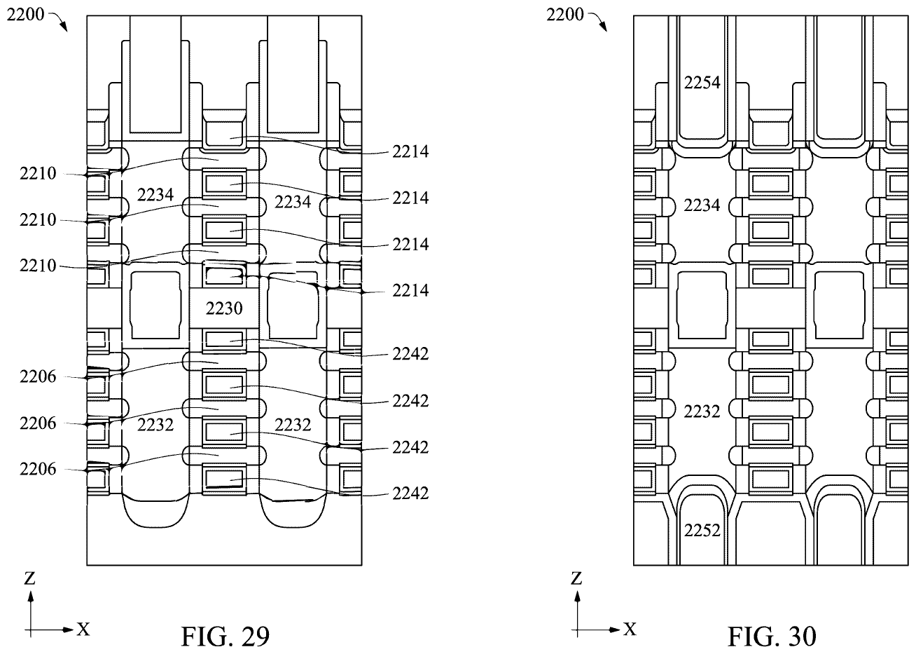

Corresponding to operation 2116 of FIG. 21, FIG. 29 is a cross-sectional view of the CFET structure 2200 including a first active gate structure 2242 and a second active gate structure 2244, at one of the various stages of fabrication. The cross-sectional view of FIG. 29 is cut along the lengthwise direction of an active region of the CFET structure 2200 (e.g., the X-direction illustrated above).

As shown, the first active gate structure 2242 wraps around each of the first nanostructures 2206; and the second active gate structure 2244 wraps around each of the third nanostructures 2210. To form the first active gate structure 2242 and second active gate structure 2244, the dummy gate structure 2202, the remaining portions of the second nanostructures 2208, and the remaining portions of the fourth nanostructures 2212 are removed. As such, a first gate trench, exposing each of the first nanostructures 2206, may be formed in the lower portion 2204-1 (e.g., the first level); and a second gate trench, exposing each of the third nanostructures 2210, may be formed in the upper portion 2204-2 (e.g., the second level). Next, the first active gate structure 2242 can be formed in the first gate trench to wrap around each of the first nanostructures 2206; and the second active gate structure 2244 can be formed in the second gate trench to wrap around each of the third nanostructures 2210.

In some embodiments, the first active gate structure 2242 can include a first gate dielectric and a first gate metal; and the second active gate structure 2244 can include a second gate dielectric and a second gate metal. The first/second gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The first/second gate dielectric may include a stack of multiple high-k dielectric materials. The first gate metal may include one or more p-type work function metals, which may include TiN, TaN, Ru, Mo, Al, WN, ZrSi₂, MoSi₂, TaSi₂, NiSi₂, WN, other suitable p-type work function materials, or combinations thereof; and the second gate metal may include one or more n-type work function metals, may include Ti, Ag, TaAl, TaAlC, TiAlN, TaC, TaCN, TaSiN, Mn, Zr, other suitable n-type work function materials, or combinations thereof.

Upon the first and second active gate structures 2242-2244 being formed, at least one p-type transistor can be formed at the first level, and at least one n-type transistor can be formed at the second level. The p-type transistor can be operatively formed based on the first nanostructures 2206, the gate structure 2242, and the pair of first epitaxial structures 2232, which can, for example, correspond to the nanostructures 1010, gate structure 1012, and epitaxial structures 1014-1016 (FIG. 10), respectively. The n-type transistor can be operatively formed based on the third nanostructures 2210, the gate structure 2244, and the pair of second epitaxial structures 2234, which can, for example, correspond to the nanostructures 1020, gate structure 1022, and epitaxial structures 1024-1026 (FIG. 10), respectively.

Corresponding to operation 2118 of FIG. 21, FIG. 30 is a cross-sectional view of the CFET structure 2200 including first connection structures 2252 and second connection structures 2254, at one of the various stages of fabrication. The cross-sectional view of FIG. 30 is cut along the lengthwise direction of an active region of the CFET structure 2200 (e.g., the X-direction illustrated above).

As shown, the first connection structure 2252 is coupled to a corresponding one of the first epitaxial structures 2232; and the second connection structure 2254 is coupled to a corresponding one of the second epitaxial structures 2234. For example, the first connection structure 2252 may be formed below the first epitaxial structure 2232; and the second connection structure 2254 may be formed above the second epitaxial structure 2234. For another example, the first connection structure 2252 may wrap around the first epitaxial structure 2232; and the second connection structure 2254 may wrap around the second epitaxial structure 2234. In some embodiments, the first connection structure 2252 and the second connection structure 2254 may each be configured as MD, as described above, which can include titanium, aluminum, nickel, tungsten, tantalum, or other suitable metal materials.

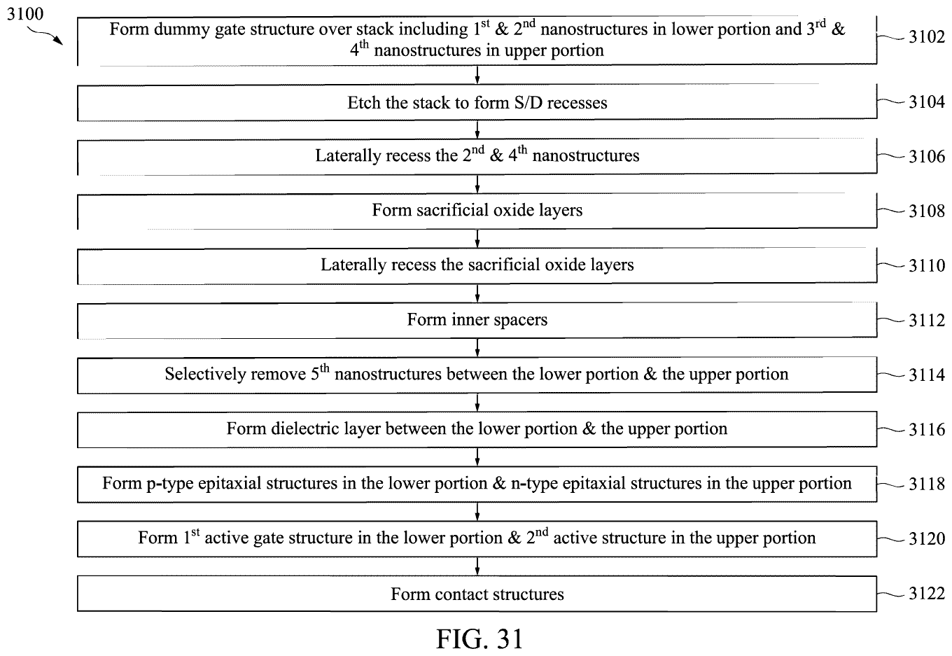

FIG. 31 illustrates a flow chart of another example method 3100 for forming a memory cell configured in a CFET structure, according to some embodiments of the present disclosure. For example, at least some of the operations (or steps) of the method 3100 can be used to form the memory cell 100 (FIG. 1), the memory cell 1500 (FIG. 15), the memory cell 1600 (FIG. 16), or the memory cell 1700 (FIG. 17) in the CFET structure, which includes a number of p-type transistors disposed at the first level on the frontside of a substrate and a number of n-type transistors disposed at the second, upper level on the frontside of the substrate.

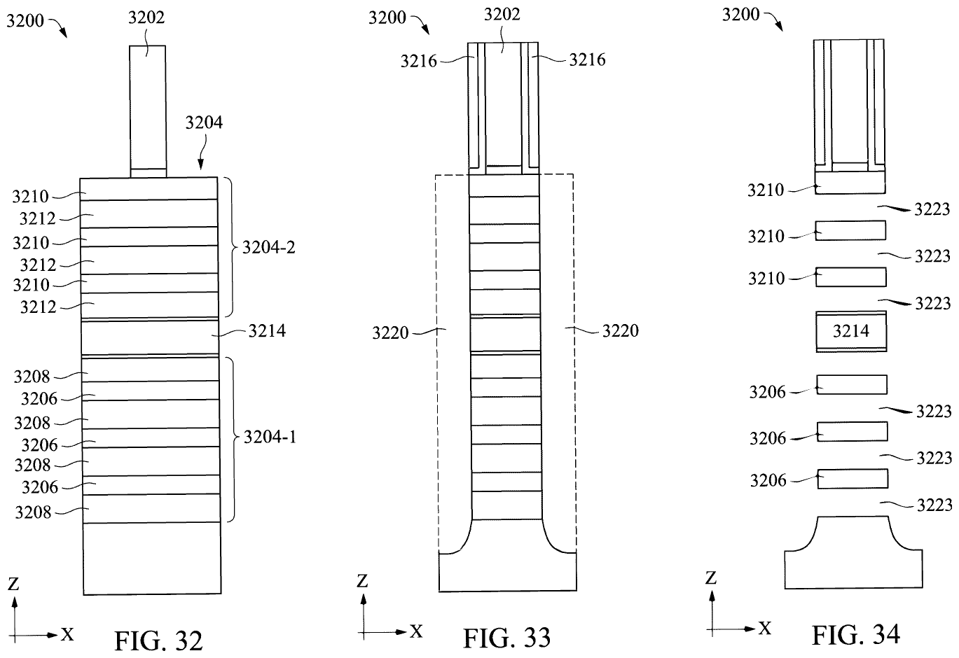

It should be appreciated that the method 3100 is merely an example, and is not intended to limit the present disclosure. Accordingly, it is understood that additional operations may be provided before, during, and after the method 3100 of FIG. 31, and that some other operations may only be briefly described herein. In some embodiments, operations of the method 3100 may be associated with cross-sectional views of a CFET structure 3200 at various fabrication stages as shown in FIGS. 32, 33, 34, 35, 36, 37, 38, 39, 40, 41, and 42, respectively, which will be discussed in further detail below.

As a brief overview, the method 3100 starts with operation 3102 of forming a number of dummy gate structures over a stack including a lower portion and an upper portion. The lower portion includes a number of first nanostructures and a number of second nanostructures alternately stacked on top of one another, and the upper portion includes a number of third nanostructures and a number of fourth nanostructures alternately stacked on top of one another. The first and third nanostructures may be formed of a first semiconductor material, and the second and fourth nanostructures may be formed of a second semiconductor material. Further, the lower portion and the upper portion may be separated from each other with a fifth nanostructure formed of a third semiconductor material. The method 3100 continues to operation 3104 of etching the stack to form source/drain recesses. The 3100 continues to operation 3106 of removing the second nanostructures and the fourth nanostructures. The method 3100 continues to operation 3108 of forming a plural number of sacrificial oxide layers each interposed between adjacent ones of the first nanostructures or between adjacent ones of the third nanostructures. The method 3100 continues to operation 3110 of laterally recessing the sacrificial oxide layers. The method 3100 continues to operation 3112 of forming a number of inner spacers. The method 3100 continues to operation 3114 of selectively removing the fifth nanostructure. The method 3100 continues to operation 3116 of forming a dielectric layer between the lower portion and the upper portion. The method 3100 continues to operation 3118 of forming a number of p-type epitaxial structures in the lower portion and a number of n-type epitaxial structures in the upper portion. The method 3100 continues to operation 3120 of forming a first active gate structure in the lower portion and a second active gate structure in the upper portion. The method 3100 continues to operation 3122 of forming a number of connection structures.

Corresponding to operation 3102 of FIG. 31, FIG. 32 is a cross-sectional view of the CFET structure 3200 including a number of dummy gate structures 3202 over a stack 3204, at one of the various stages of fabrication. The cross-sectional view of FIG. 32 is cut along the lengthwise direction of an active region of the CFET structure 3200 (e.g., the X-direction illustrated above).

In some embodiments, the stack 3204 may be formed over a semiconductor substrate 3201, followed by the dummy gate structure 3202 formed over the stack 3204. The stack 3204 can extend along the X-direction, and the dummy gate structure 3202 can extend along the Y-direction to straddle or otherwise traverse the stack 3204. The stack 3204 includes a lower portion 3204-1 and an upper portion 3204-2, which can correspond to the first level and the second level on the frontside of the substrate (e.g., FIGS. 10, 14, 24), respectively. The lower portion 3204-1 includes a number of first nanostructures 3206 and a number of second nanostructures 3208 alternately stacked on top of one another, and the upper portion 3204-2 includes a number of third nanostructures 3210 and a number of fourth nanostructures 3212 alternately stacked on top of one another.

The substrate 3201, the first nanostructures 3206, and the third nanostructures 3210 may be formed of a first semiconductor material, e.g., silicon (Si), while the second nanostructures 3208 and the fourth nanostructures 3212 may be formed of a second semiconductor material, e.g., silicon germanium (Si₁₋ₓGeₓ). Further, the lower portion 3204-1 and the upper portion 3204-2 are separated from each other with a fifth nanostructure 3214 formed of a third semiconductor material, e.g., silicon germanium (Si_{1-y}Ge_{y}). In some embodiments, the molar ratio “x” of the second semiconductor material may be less than 0.5, and the molar ratio “y” of the third semiconductor material may be higher than 0.5.

The nanostructures 3206 to 3212 can be epitaxially grown from the semiconductor substrate 3201. For example, each of the nanostructures 3206 to 3212 may be grown by a molecular beam epitaxy (MBE) process, a chemical vapor deposition (CVD) process such as a metal organic CVD (MOCVD) process, and/or other suitable epitaxial growth processes. Upon growing the nanostructures 3206 to 3212 on the substrate 3201 as a blanket stack, the blanket stack may be patterned to form the stack 3204 shown in FIG. 32 (e.g., having a lengthwise direction in the X-direction and a relatively narrow width in the Y-direction). After the stack 3204 is formed, the dummy gate structure 3202, including a dummy gate dielectric (e.g., silicon oxide) and a dummy gate material (e.g., polysilicon), is formed to straddle the stack 3204.

Corresponding to operation 3104 of FIG. 31, FIG. 33 is a cross-sectional view of the CFET structure 3200 in which source/drain recesses 3220 are formed, at one of the various stages of fabrication. The cross-sectional view of FIG. 33 is cut along the lengthwise direction of an active region of the CFET structure 3200 (e.g., the X-direction illustrated above).

To form the source/drain recesses 3220, a pair of gate spacers 3216 may be formed on opposite sidewalls of the dummy gate structure 3202. Next, with the dummy gate structure 3202 and the gate spacers 3216 serving as a mask, the stack 3204 is again patterned to form the source/drain recesses 3220 using an anisotropic etching process. Such an anisotropic etching process can include reactive ion etch (RIE), neutral beam etch (NBE), the like, or combinations thereof.

Corresponding to operation 3106 of FIG. 31, FIG. 34 is a cross-sectional view of the CFET structure 3200 in which the second nanostructures 3208 and the fourth nanostructures 3212 are removed, at one of the various stages of fabrication. The cross-sectional view of FIG. 34 is cut along the lengthwise direction of an active region of the CFET structure 3200 (e.g., the X-direction illustrated above).

In some embodiments, the second nanostructures 3208 and the fourth nanostructures 3212 may be selectively removed (e.g. etched), with the first nanostructures 3206, the third nanostructures 3210, and the fifth nanostructure 3214 remaining substantially intact. The second nanostructures 3208 and the fourth nanostructures 3212 may be completely removed using a hydrogen chloride (HCl) gas isotropic etching process, which etches SiGe with the lower Ge composition (e.g., Si₁₋ₓGeₓ) without attacking Si or SiGe with the higher Ge composition (e.g., Si_{1-y}Ge_{y}). As such, a plural number of spaces 3223 can be formed. Each of the spaces 3223 can be vertically interposed between the substrate 3201 and a bottommost one of the first nanostructures 3206, between the adjacent ones of the first nanostructures 3206, between a topmost one of the first nanostructures 3206 and the fifth nanostructure 3214, between the fifth nanostructure 3214 and a bottommost one of the third nanostructures 3210, or between the adjacent ones of the third nanostructures 3210, as shown in FIG. 34.

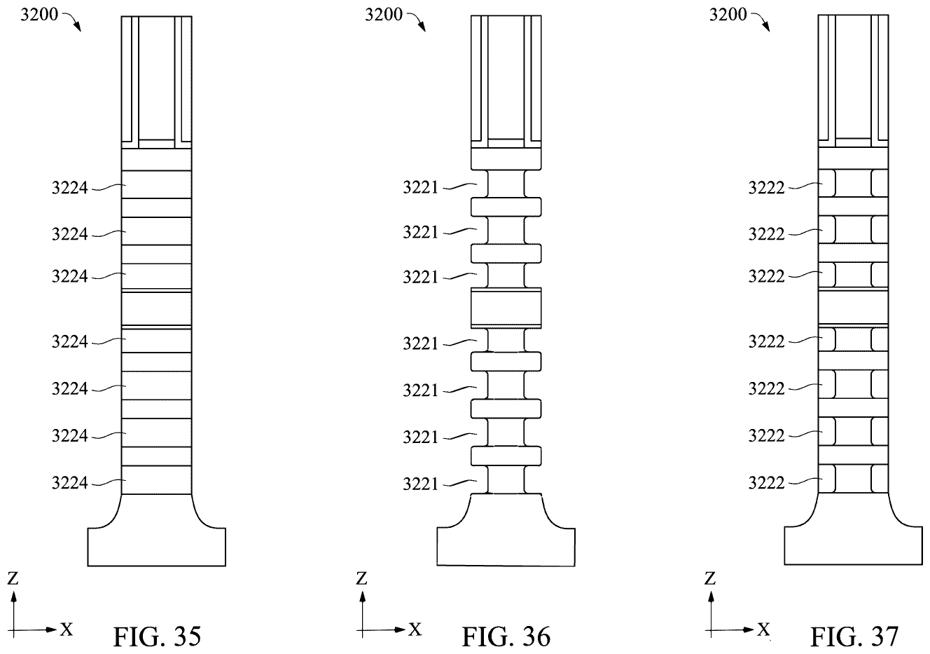

Corresponding to operation 3108 of FIG. 31, FIG. 35 is a cross-sectional view of the CFET structure 3200 including a plural number of sacrificial oxide layers 3224, at one of the various stages of fabrication. The cross-sectional view of FIG. 35 is cut along the lengthwise direction of an active region of the CFET structure 3200 (e.g., the X-direction illustrated above).

As shown, the sacrificial oxide layers 3224 are formed at least in the spaces 3223, respectively. In some embodiments, the sacrificial oxide layers 3224 may be formed using, e.g., a conformal deposition process to deposit an oxide material and one or more subsequent isotropic or anisotropic etching processes to remove the excessive oxide material on the sidewalls of the stack 3204. As such, the sacrificial oxide layers 3224 can each be vertically interposed between the substrate 3201 and the bottommost first nanostructures 3206, between the adjacent first nanostructures 3206, between the topmost first nanostructure 3206 and the fifth nanostructure 3214, between the fifth nanostructure 3214 and the bottommost third nanostructure 3210, or between the adjacent third nanostructures 3210, as shown in FIG. 35.

Corresponding to operation 3110 of FIG. 31, FIG. 36 is a cross-sectional view of the CFET structure 3200 in which the sacrificial oxide layers 3224 are laterally recessed, at one of the various stages of fabrication. The cross-sectional view of FIG. 36 is cut along the lengthwise direction of an active region of the CFET structure 3200 (e.g., the X-direction illustrated above).

As shown, respective end portions of each of the sacrificial oxide layers 3224 are removed (e.g., etched) using a “pull-back” process to pull each of the sacrificial oxide layers 3224 back by a pull-back distance. For example, the pull-back process may include a hydrofluoric acid (HF) gas isotropic etching process, which etches silicon oxide without attacking Si or SiGe with the higher Ge composition (e.g., Si_{1-y}Ge_{y}). As such, the nanostructures 3206 (Si), 3210 (Si), and 3214 (Si_{1-y}Ge_{y}) may remain substantially intact during this process, and a number of recess 3221, each inwardly extending from the source/drain recess 3220, can be formed.

Corresponding to operation 3112 of FIG. 31, FIG. 37 is a cross-sectional view of the CFET structure 3200 including a number of inner spacers 3222, at one of the various stages of fabrication. The cross-sectional view of FIG. 37 is cut along the lengthwise direction of an active region of the CFET structure 3200 (e.g., the X-direction illustrated above).

The inner spacers 3222 can be formed by filling the recesses 3221 with a dielectric material. For example, the inner spacers 3222 can be deposited using, e.g., a conformal deposition process and subsequent isotropic or anisotropic etch back to remove excess spacer material on the sidewalls of the stack 3204. The dielectric material, used to form the inner spacer 3222, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

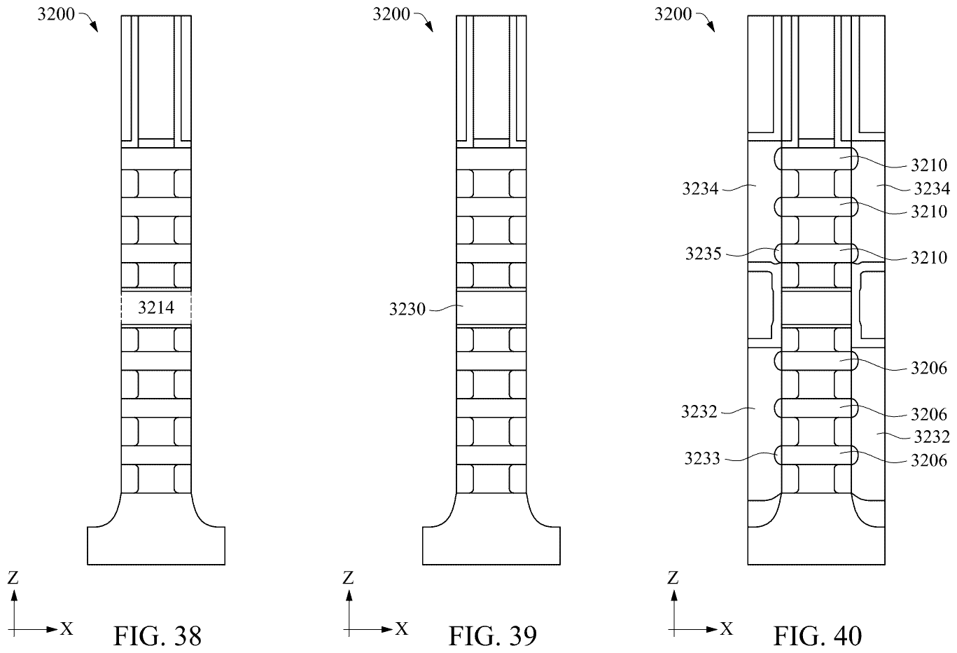

Corresponding to operation 3114 of FIG. 31, FIG. 38 is a cross-sectional view of the CFET structure 3200 in which the fifth nanostructure 3214 is removed, at one of the various stages of fabrication. The cross-sectional view of FIG. 38 is cut along the lengthwise direction of an active region of the CFET structure 3200 (e.g., the X-direction illustrated above).

After forming the inner spacers 3222, the fifth nanostructure 3214 can be selectively removed using an isotropic etching process that etches Si_{1-y}Ge_{y} without attacking Si. As such, the first nanostructures 3206 (Si) and third nanostructures 3210 (Si) can remain substantially intact, the fifth nanostructure 3214 (Si_{1-y}Ge_{y}) can be completely removed, and the remaining portions of the sacrificial oxide layers 3224 can remain with the protection of the inner spacers 3222.

Corresponding to operation 3116 of FIG. 31, FIG. 39 is a cross-sectional view of the CFET structure 3200 including a dielectric layer 3230, at one of the various stages of fabrication. The cross-sectional view of FIG. 39 is cut along the lengthwise direction of an active region of the CFET structure 3200 (e.g., the X-direction illustrated above).

After the fifth nanostructure 3214 is removed, a space is formed between the lower portion 3204-1 and the upper portion 3204-2. The dielectric layer 3230 can be formed by filling the space with a dielectric material. The dielectric material, used to form the dielectric layer 3230, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating structure for transistors.

Corresponding to operation 3118 of FIG. 31, FIG. 40 is a cross-sectional view of the CFET structure 3200 including a number of first epitaxial structures 3232 and a number of second epitaxial structures 3234, at one of the various stages of fabrication. The cross-sectional view of FIG. 40 is cut along the lengthwise direction of an active region of the CFET structure 3200 (e.g., the X-direction illustrated above).

As shown, a pair of the first epitaxial structure 3232 are coupled to ends of each of the first nanostructures 3206, respectively; and a pair of the second epitaxial structure 3234 are coupled to ends of each of the third nanostructures 3210, respectively. The first epitaxial structures 3232 can be formed through a first epitaxial growth process, followed by a second epitaxial growth process for forming the second epitaxial structures 3234. Further, between the first epitaxial growth process and the second epitaxial growth process, one or more dielectric layers 3230 can be formed to electrically isolate the first epitaxial structures 3232 and the second epitaxial structures 3234. Each of the first epitaxial growth process and the second epitaxial growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. Specifically, the first epitaxial structures 3232 can be grown from the first nanostructures 3206, and the second epitaxial structures 3234 can be grown from the third nanostructures 3210.

The first epitaxial structures 3232 and the second epitaxial structures 3234 may each include silicon germanium (SiGe), indium arsenide (InAs), indium gallium arsenide (InGaAs), indium antimonide (InSb), gallium arsenide (GaAs), gallium antimonide (GaSb), indium aluminum phosphide (InAlP), indium phosphide (InP), any other suitable material, or combinations thereof. Further, in-situ doping (ISD) may be applied during the formation of each of the first epitaxial structures 3232 and the second epitaxial structures 3234. For example, the first epitaxial structures 3232 can be doped by implanting p-type dopants, e.g., boron (B), etc., into them; and the second epitaxial structures 3234 can be doped by implanting n-type dopants, e.g., arsenic (As), phosphorous (P), etc., into them. In some embodiments, the first epitaxial structure 3232 can be coupled to each of the first nanostructures 3206 through a lightly doped region 3233 (e.g., SiGeB); and the second epitaxial structure 3234 can be coupled to each of the third nanostructures 3210 through a lightly doped region 3235 (e.g., SiP).

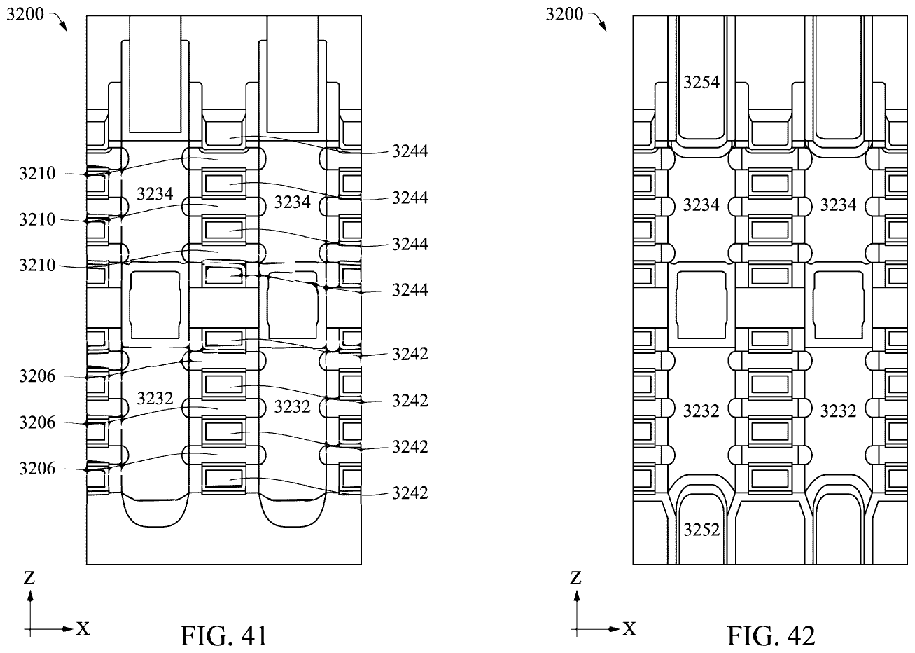

Corresponding to operation 3120 of FIG. 31, FIG. 41 is a cross-sectional view of the CFET structure 3200 including a first active gate structure 3242 and a second active gate structure 3244, at one of the various stages of fabrication. The cross-sectional view of FIG. 41 is cut along the lengthwise direction of an active region of the CFET structure 3200 (e.g., the X-direction illustrated above).

As shown, the first active gate structure 3242 wraps around each of the first nanostructures 3206; and the second active gate structure 3244 wraps around each of the third nanostructures 3210. To form the first active gate structure 3242 and second active gate structure 3244, the dummy gate structure 3202, and the remaining portions of the sacrificial oxide layers 3224 are removed. As such, a first gate trench, exposing each of the first nanostructures 3206, may be formed in the lower portion 3204-1 (e.g., the first level); and a second gate trench, exposing each of the third nanostructures 3210, may be formed in the upper portion 3204-2 (e.g., the second level). Next, the first active gate structure 3242 can be formed in the first gate trench to wrap around each of the first nanostructures 3206; and the second active gate structure 3244 can be formed in the second gate trench to wrap around each of the third nanostructures 3210.

In some embodiments, the first active gate structure 3242 can include a first gate dielectric and a first gate metal; and the second active gate structure 3244 can include a second gate dielectric and a second gate metal. The first/second gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The first/second gate dielectric may include a stack of multiple high-k dielectric materials. The first gate metal may include one or more p-type work function metals, which may include TiN, TaN, Ru, Mo, Al, WN, ZrSi₂, MoSi₂, TaSi₂, NiSi₂, WN, other suitable p-type work function materials, or combinations thereof; and the second gate metal may include one or more n-type work function metals, may include Ti, Ag, TaAl, TaAlC, TiAlN, TaC, TaCN, TaSiN, Mn, Zr, other suitable n-type work function materials, or combinations thereof.

Upon the first and second active gate structures 3242-3244 being formed, at least one p-type transistor can be formed at the first level, and at least one n-type transistor can be formed at the second level. The p-type transistor can be operatively formed based on the first nanostructures 3206, the gate structure 3242, and the pair of first epitaxial structures 3232, which can, for example, correspond to the nanostructures 1010, gate structure 1012, and epitaxial structures 1014-1016 (FIGS. 10, 14, 24), respectively. The n-type transistor can be operatively formed based on the third nanostructures 3210, the gate structure 3244, and the pair of second epitaxial structures 3234, which can, for example, correspond to the nanostructures 1020, gate structure 1022, and epitaxial structures 1024-1026 (FIGS. 10, 14, 24), respectively.

Corresponding to operation 3122 of FIG. 31, FIG. 42 is a cross-sectional view of the CFET structure 3200 including first connection structures 3252 and second connection structures 3254, at one of the various stages of fabrication. The cross-sectional view of FIG. 42 is cut along the lengthwise direction of an active region of the CFET structure 3200 (e.g., the X-direction illustrated above).

As shown, the first connection structure 3252 is coupled to a corresponding one of the first epitaxial structures 3232; and the second connection structure 3254 is coupled to a corresponding one of the second epitaxial structures 3234. For example, the first connection structure 3252 may be formed below the first epitaxial structure 3232; and the second connection structure 3254 may be formed above the second epitaxial structure 3234. For another example, the first connection structure 3252 may wrap around the first epitaxial structure 3232; and the second connection structure 3254 may wrap around the second epitaxial structure 3234. In some embodiments, the first connection structure 3252 and the second connection structure 3254 may each be configured as MD, as described above, which can include titanium, aluminum, nickel, tungsten, tantalum, or other suitable metal materials.

In one aspect of the present disclosure, a memory device is disclosed. The memory device includes a substrate having a first side and a second side opposite to each other; a first transistor, a second transistor, and a third transistor formed at a first level on the first side of the substrate, the first to third transistors each formed with a first conductivity; and a fourth transistor, a fifth transistor, a sixth transistor, and a seventh transistor formed at a second level on the first side of the substrate, the fourth to seventh transistors each formed with a second conductivity, wherein the first level is vertically disposed with respect to the second level. The first to seventh transistors operatively form a Static Random Access Memory (SRAM) cell.

In another aspect of the present disclosure, a memory device is disclosed. The memory device includes a memory array comprising a plurality of memory cells. Each of the plurality of memory cells comprises at least first, second, third, fourth, fifth, sixth, and seventh transistors formed on a side of a substrate. The first to third transistors of each of the plurality of memory cells, with a p-type conductivity, are formed at a first level on the side, and the fourth to seventh transistors of each of the plurality of memory cells, with an n-type conductivity, are formed at a second level on the side.

In yet another aspect of the present disclosure, a method for forming semiconductor devices is disclosed. The method includes forming, at a first level on a first side of a substrate, a first active region extending along a first lateral direction. The method includes forming, at the first level, a first gate structure, a second gate structure, a third gate structure, and a fourth gate structure, the first to fourth gate structure extending along a second lateral direction perpendicular to the first lateral direction and traversing the first active region. The method includes forming, at a second level over the first level on the first side, a second active region extending in the first lateral direction. The method includes forming, at the second level, a fifth gate structure, a sixth gate structure, a seventh gate structure, and an eighth gate structure, the fifth to eighth gate structure extending along the second lateral direction and traversing the second active region. The first active region and the first to fourth gate structures operatively form a first transistor, a second transistor, and a third transistor of a memory cell that have a first conductivity, the second active region and the fifth to eighth gate structures operatively form a fourth transistor, a fifth transistor, a sixth transistor, and a seventh transistor of the memory cell that have a second conductivity.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a substrate having a first side and a second side opposite to each other;
a first transistor, a second transistor, and a third transistor formed at a first level on the first side of the substrate, the first to third transistors each formed with a first conductivity; and
a fourth transistor, a fifth transistor, a sixth transistor, and a seventh transistor formed at a second level on the first side of the substrate, the fourth to seventh transistors each formed with a second conductivity, wherein the first level is vertically disposed with respect to the second level;
wherein the first to seventh transistors operatively form a Static Random Access Memory (SRAM) cell.

2. The memory device of claim 1, wherein the first to third transistors are formed based on a first active region, a first gate section, a second gate section, a third gate section, and a fourth gate section disposed at the first level, and wherein the fourth to seventh transistors are formed based on a second active region, a fifth gate section, a sixth gate section, a seventh gate section, and an eighth gate section disposed at the second level.

3. The memory device of claim 2, wherein the first active region is vertically aligned with the second active region, the first gate section is vertically aligned with the fifth gate section, the second gate section is vertically aligned with the sixth gate section, the third gate section is vertically aligned with the seventh gate section, and the fourth gate section is vertically aligned with the eighth gate section.

4. The memory device of claim 1, wherein the first and second transistors operatively serve as pull-up transistors of the SRAM cell, the third transistor operatively serves as a read pass-gate transistor of the SRAM cell, the fourth and seventh transistors operatively serve as write pass-gate transistors of the SRAM cell, and the fifth and sixth transistors operatively serve as pull-down transistors of the SRAM cell.

5. The memory device of claim 4, wherein the first conductivity is p-type and the second conductivity is n-type, and wherein the second level is vertically above the first level on the first side of the substrate.

6. The memory device of claim 1, wherein the first and second transistors operatively serve as pull-down transistors of the SRAM cell, the third transistor operatively serves as a read pass-gate transistor of the SRAM cell, the fourth and seventh transistors operatively serve as write pass-gate transistors of the SRAM cell, and the fifth and sixth transistors operatively serve as pull-up transistors of the SRAM cell.

7. The memory device of claim 6, wherein the first conductivity is n-type and the second conductivity is p-type, and wherein the second level is vertically below the first level on the first side of the substrate.

8. The memory device of claim 1, wherein the fifth and sixth transistors are arranged next to each other along a lateral direction, with the fourth and seventh transistors arranged on opposite sides of the fifth and sixth transistors along the lateral direction, respectively.

9. The memory device of claim 8, wherein the third transistor is vertically aligned with one of the fourth transistor or the seventh transistor.

10. The memory device of claim 1, further comprising:
a first interconnect structure, a second interconnect structure, a third interconnect structure, and a fourth interconnect structure formed at a third level on the first side of the substrate, wherein the third level is vertically disposed with respect to the first level and the second level; and
a fifth interconnect structure, a sixth interconnect structure, a seventh interconnect structure, a first internal contact structure, and a second internal contact structure formed at a level on the second side of the substrate;
wherein each of the first to seventh interconnect structures and the first to second internal contact structures extends along a lateral direction in which the first to third transistors and the fourth to seventh transistors are arranged with respect to one another.

11. The memory device of claim 10, wherein the first interconnect structure operatively serves as a write word line of the SRAM cell, the second interconnect structure operatively serves as a first write bit line of the SRAM cell, the third interconnect structure operatively serves as a second write bit line of the SRAM cell, the fourth interconnect structure operatively serves as a first power rail of the SRAM cell that carries a reference voltage.

12. The memory device of claim 11, wherein the fifth interconnect structure operatively serves as a second power rail of the SRAM cell that carries a supply voltage, the sixth interconnect structure operatively serves as a read word line of the SRAM cell, and the seventh interconnect structure operatively serves as a read bit line of the SRAM cell.

13. A memory device, comprising:
a memory array comprising a plurality of memory cells;
wherein each of the plurality of memory cells comprises at least first, second, third, fourth, fifth, sixth, and seventh transistors formed on a side of a substrate;
wherein the first to third transistors of each of the plurality of memory cells, with a p-type conductivity, are formed at a first level on the side, and the fourth to seventh transistors of each of the plurality of memory cells, with an n-type conductivity, are formed at a second level on the side.

14. The memory device of claim 13, wherein the first to third transistors are formed over four first gate structures extending along a first lateral direction, with the first and second transistors disposed immediately next to each other along a second lateral direction perpendicular to the first lateral direction and with the third transistor disposed immediately next to the first or second transistor along the second lateral direction.

15. The memory device of claim 14, wherein the fourth to seventh transistors are formed over four second gate structures extending along the first lateral direction, with the fifth and sixth transistors disposed immediately next to each other along the second lateral direction and with the fourth transistor and seventh transistor disposed on opposite sides of the fifth and sixth transistors along the second lateral direction.

16. The memory device of claim 15, wherein the third transistor is vertically aligned with the fourth or seventh transistor.

17. The memory device of claim 13, wherein a first one of the plurality of memory cells are formed based on a first active region and a first group of four gate structures at the first level and a second active region and a second group of four gate structures at the second level, and a second one of the plurality of memory cells are formed based on a third active region and a third group of four gate structures at the first level and a fourth active region and a fourth group of four gate structures at the second level.

18. The memory device of claim 17, wherein the first to fourth groups of gate structures extend along a first lateral direction, and the first to fourth active regions extend along a second lateral direction perpendicular to the first lateral direction, and wherein the first and third active regions are spaced from each other along the first lateral direction and the second and fourth active regions are spaced from each other along the first lateral direction.

19. A method for forming semiconductor devices, comprising:
forming, at a first level on a first side of a substrate, a first active region extending along a first lateral direction;
forming, at the first level, a first gate structure, a second gate structure, a third gate structure, and a fourth gate structure, the first to fourth gate structure extending along a second lateral direction perpendicular to the first lateral direction and traversing the first active region;
forming, at a second level over the first level on the first side, a second active region extending in the first lateral direction; and
forming, at the second level, a fifth gate structure, a sixth gate structure, a seventh gate structure, and an eighth gate structure, the fifth to eighth gate structure extending along the second lateral direction and traversing the second active region;
wherein the first active region and the first to fourth gate structures operatively form a first transistor, a second transistor, and a third transistor of a memory cell that have a first conductivity, the second active region and the fifth to eighth gate structures operatively form a fourth transistor, a fifth transistor, a sixth transistor, and a seventh transistor of the memory cell that have a second conductivity.

20. The method of claim 19, further comprising:
forming, at a third level over the second level on the first side, a first interconnect structure, a second interconnect structure, a third interconnect structure, and a fourth interconnect structure, the first to third interconnect structures extending along the first lateral direction; and
forming, at a level on a second side of the substrate, a fifth interconnect structure, a sixth interconnect structure, a seventh interconnect structure, a first internal contact structure, and a second internal contact structure, the fifth to seventh interconnect structures and the first and second internal contact structures extending along the first lateral direction;
wherein the first interconnect structure operatively serves as a write word line of the memory cell, the second interconnect structure operatively serves as a first write bit line of the memory cell, the third interconnect structure operatively serves as a second write bit line of the memory cell, the fourth interconnect structure operatively serves as a first power rail of the memory cell that carries a reference voltage; and
wherein the fifth interconnect structure operatively serves as a second power rail of the memory cell that carries a supply voltage, the sixth interconnect structure operatively serves as a read word line of the memory cell, and the seventh interconnect structure operatively serves as a read bit line of the memory cell.
